(19) United States
(12) Patent Application Publication
(10) Pub. No.: US 2024/0324239 A1
(43) Pub. Date: Sep. 26, 2024

(54) SEMICONDUCTOR MEMORY DEVICE

(71) Applicant: SAMSUNG ELECTRONICS CO., LTD., Suwon-si (KR)

(72) Inventors: Daewon Ha, Suwon-si (KR); Kyunghwan Lee, Suwon-si (KR); Myunghun Woo, Suwon-si (KR)

(21) Appl. No.: 18/612,011

(22) Filed: Mar. 21, 2024

(30) Foreign Application Priority Data
Mar. 24, 2023 (KR) 10-2023-0039155
May 9, 2023 (KR) 10-2023-0059962

(51) Int. Cl. H10B 53/30; G11C 5/06; H01L 21/28; H01L 29/51; H01L 29/78; H10B 51/10; H10B 51/30; H10B 53/10

(52) U.S. Cl. CPC H10B 53/30; G11C 5/063; H01L 29/40111; H01L 29/516; H01L 29/78391; H10B 51/10; H10B 51/30; H10B 53/10

(57) ABSTRACT

A semiconductor memory device includes a plurality of memory cells each including a first vertical channel transistor (VCT) and a second VCT arranged in a vertical direction and connected to each other in series, the plurality of memory cells respectively including a plurality of ferroelectric capacitors connected to the second VCT in parallel and arranged in the vertical direction, wherein the plurality of memory cells are arranged in columns and rows in a first horizontal direction and a second horizontal direction that is different from the first horizontal direction.

### CROSS-REFERENCE TO RELATED APPLICATION

This application is based on and claims priority under 35 U.S.C. § 119 to Korean Patent Application Nos. 10-2023-0039155, filed on Mar. 24, 2023 and 10-2023-0059962 filed on May 9, 2023 in the Korean Intellectual Property office, the disclosures of which are incorporated by reference herein in their entirety.

### BACKGROUND

As miniaturization, multi-functionalization, and high performance of electronic products are required, large capacity semiconductor memory devices are required. To provide semiconductor memory devices with large capacity and increased integration, various types of semiconductor memory devices are being studied, and semiconductor memory devices including ferroelectric capacitors instead of general capacitors are also proposed.

### SUMMARY

The present disclosure relates to a semiconductor memory device including a ferroelectric capacitor with increased integration and low process difficulty.

According to an aspect of the present disclosure, a semiconductor memory device is provided, in which the device includes a plurality of memory cells each including a first vertical channel transistor (VCT) and a second VCT arranged in a vertical direction and connected to each other in series. The plurality of memory cells respectively include a plurality of ferroelectric capacitors connected to the second VCT in parallel and arranged in the vertical direction, wherein the plurality of memory cells are arranged in columns and rows in a first horizontal direction and a second horizontal direction that is different from the first horizontal direction.

According to another aspect of the present disclosure, there is provided a semiconductor memory device including a substrate, a first conductive line on the substrate, a first gate electrode on the first conductive line, a first impurity region arranged between the first conductive line and the first gate electrode, a first channel region surrounding side surfaces of the first gate electrode, a second impurity region on the first channel region, a second conductive line on the first gate electrode, a plurality of word lines apart from each other in a vertical direction on the second conductive line, a second gate electrode configured to penetrate the plurality of word lines and the second conductive line and extending, on the first gate electrode, a ferroelectric pattern arranged between the plurality of word lines and an upper side portion of the second gate electrode, a second channel region surrounding side surfaces of a lower side portion of the second gate electrode on the second impurity region, and a third impurity region connected to the second channel region, wherein the first impurity region, the first channel region, the second impurity region, and the first gate electrode constitute a first vertical channel transistor (VCT), and wherein the second impurity region, the second channel region, the third impurity region, and a lower side portion of the second gate electrode constitute a second VCT.

According to another aspect of the present disclosure, there is provided a semiconductor memory device including a substrate, a first conductive line extending in a first horizontal direction on the substrate, a first gate electrode extending in a second horizontal direction orthogonal to the first horizontal direction on the first conductive line, a first channel structure including a first impurity region arranged between the first conductive line and the first gate electrode, a first channel region surrounding side surfaces of the first gate electrode, and a second impurity region connected to the first channel region and covering the first gate electrode, a second conductive line connected to and adjacent to the first channel structure in the first horizontal direction on the first gate electrode, a plurality of word lines apart from each other in a vertical direction on the second conductive line, a second gate electrode being apart from the plurality of word lines and the second conductive line on the first gate electrode, the second gate electrode configured to penetrate the plurality of word lines and the second conductive line and extending in the vertical direction toward the substrate, a ferroelectric pattern arranged between the plurality of word lines and the second gate electrode, and surrounding side surfaces of an upper side portion of the second gate electrode, and a second channel structure surrounding side surfaces of a lower side portion of the second gate electrode, the second channel structure including a third impurity region connected to the second channel region and arranged between the second conductive line and the second gate electrode, wherein the first impurity region, the first channel region, the second impurity region, and the first gate electrode constitute a first vertical channel transistor (VCT), wherein the second impurity region, the second channel region, the third impurity region, and the lower side portion of the second gate electrode constitute a second VCT connected to the first VCT in series, and wherein portions of the ferroelectric pattern arranged between the upper side portion of the second gate electrode and the plurality of word lines constitute a plurality of ferroelectric capacitors arranged in the vertical direction and connected to the second VCT in parallel.

### BRIEF DESCRIPTION OF THE DRAWINGS

Implementations will be more clearly understood from the following detailed description taken in conjunction with the accompanying drawings in which:

FIG. 1 is a cross-sectional view of a cell array of a semiconductor memory device, according to some implementations;

FIGS. 2A through 18C are diagrams illustrating a process sequence of a method of manufacturing a semiconductor memory device according to some implementations; and FIGS. 19A through 19C are diagrams of a semiconductor memory device;

FIGS. 20A through 20D are plan views of a semiconductor memory device according to some implementations; and

FIGS. 21A through 22C are diagrams illustrating a process sequence of a method of manufacturing a semiconductor memory device, according to some implementations, and FIGS. 23A through 23C are diagrams of a semiconductor memory device.

### DETAILED DESCRIPTION

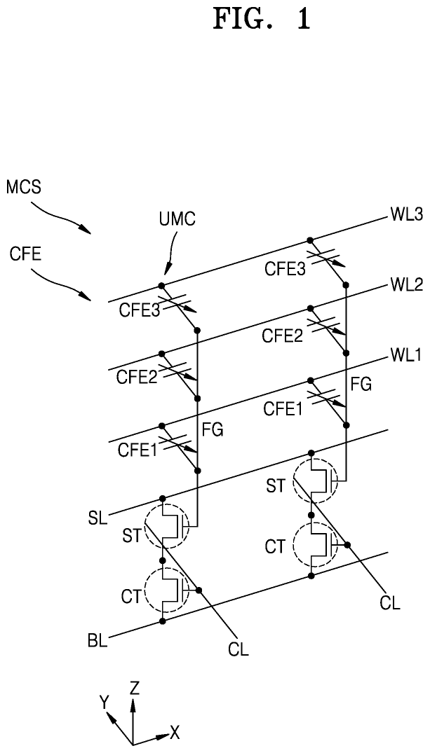

FIG. 1 is a cross-sectional view of a cell array MCS of a semiconductor memory device, according to some implementations.

Referring to FIG. 1, the cell array MCS of a semiconductor memory device according to some implementations includes a plurality of memory cells UMC. Although FIG. 1 illustrates that the plurality of memory cells UMC are arranged in a first horizontal direction (X direction), this is for convenience of illustration, and the plurality of memory cells UMC may be arranged in columns and rows in the first horizontal direction (X direction) and in a second horizontal direction (Y direction) different from the first horizontal direction (X direction). In some implementations, the second horizontal direction (Y direction) may be orthogonal to the first horizontal direction (X direction). In some implementations, the second horizontal direction (Y direction) may be a direction at an acute angle to the first horizontal direction (X direction).

Each of the plurality of memory cells UMC includes a 2 transistor n capacitor (2TnC) memory cell including two transistors and a plurality of capacitors. Each of the plurality of capacitors included in the memory cell UMC may include a ferroelectric capacitor. For example, each of the plurality of memory cells UMC may include a 2 transistor n ferroelectric capacitor (2TnCFE) memory cell including two transistors and a plurality of ferroelectric capacitors, and a semiconductor memory device including the cell array MCS including the plurality of memory cells UMC may be referred to as a 2 transistor n capacitor ferroelectric random access memory (2TnCFeRAM).

Each of the plurality of memory cells UMC includes a first transistor CT, a second transistor ST, and pluralities of ferroelectric capacitors CFE1, CFE2, and CFE3 (hereinafter, CFE). The plurality of ferroelectric capacitors CFE included in the memory cell UMC may be stacked in a vertical direction (Z direction) with respect to the first transistor CT and the second transistor ST. The plurality of ferroelectric capacitors CFE may be arranged on the first transistor CT and the second transistor ST but are not limited thereto. For example, the plurality of ferroelectric capacitors CFE may also be arranged under the first transistor CT and the second transistor ST.

The first transistor CT, the second transistor ST, and the plurality of ferroelectric capacitors CFE may be arranged in the vertical direction (Z direction). For example, the first transistor CT, the second transistor ST, and the plurality of ferroelectric capacitors CFE may be sequentially arranged in the vertical direction (Z direction). Alternatively, the plurality of ferroelectric capacitors CFE, the second transistor ST, and the first transistor CT may be sequentially arranged in the vertical direction (Z direction). For example, a semiconductor memory device may be formed by forming a first structure, in which the first transistor CT, the second transistor ST, and the plurality of ferroelectric capacitors CFE are sequentially arranged in the vertical direction (Z direction), and then flipping and bonding the first structure onto a second structure including a periphery circuit.

Each of the plurality of ferroelectric capacitors CFE included in one memory cell UMC may be arranged in the vertical direction (Z direction). FIG. 1 illustrates that one memory cell UMC includes three ferroelectric capacitors CFE including a first ferroelectric capacitor CFE1, a second ferroelectric capacitor CFE2, and a third ferroelectric capacitor CFE3, but the implementations are not limited thereto, and one memory cell UMC may also include four or more ferroelectric capacitors CFE.

The first transistor CT may be referred to as a control transistor, and the second transistor ST may be referred to as a storage transistor. A bit line BL may be connected to a source of the first transistor CT, and a storage line SL may be connected to a drain of the second transistor ST. A drain of the first transistor CT may be connected to a source of the second transistor ST. The first transistor CT may be connected to the second transistor ST in series. A control line CL may be connected to a gate of the first transistor CT, and a floating gate FG may be connected to a gate of the second transistor ST. The floating gate FG may be connected to one end of each of the plurality of ferroelectric capacitors CFE, and each of a plurality of word lines WL1, WL2, and WL3 (hereinafter, WL) may be connected to the other end thereof. FIG. 1 illustrates that one memory cell UMC includes three word lines WL including a first word line WL1, a second word line WL2, and a third word line WL3, but implementations are is not limited thereto, and one memory cell UMC may include four or more word lines WL. In some embodiments, the number of word lines WL arranged in the vertical direction (Z direction) may be the same as the number of ferroelectric capacitors CFE included in one memory cell UMC.

For example, when one memory cell UMC includes three ferroelectric capacitors CFE including the first ferroelectric capacitor CFE1, the second ferroelectric capacitor CFE2, and the third ferroelectric capacitor CFE3, the first word line WL1, the second word line WL2, and the third word line WL3 may be respectively connected to the other ends of the first ferroelectric capacitor CFE1, the second ferroelectric capacitor CFE2, and the third ferroelectric capacitor CFE3. The plurality of ferroelectric capacitors CFE may be connected to the floating gate FG in parallel.

The memory cell UMC may be selected by the control line CL, read READ and write WRITE of information in the memory cell UMC may be selected by the bit line BL, write WRITE and erase ERASE of information in the memory cell UMC may be selected by the source line SL, and read READ, the write WRITE, and the erase ERASE of information in the memory cell UMC may be selected by the word line WL.

The bit line BL may extend in the first horizontal direction (X direction). The control line CL may extend in the second horizontal direction (Y direction). The source line SL may extend in the first horizontal direction (X direction). The floating gate FG may extend in the vertical direction (Z direction).

The plurality of word lines WL are respectively connected to the plurality of ferroelectric capacitors CFE of each of the plurality of memory cells UMC arranged in columns and rows in the first horizontal direction (X direction) and the second horizontal direction (Y direction). For example, the first word line WL1 may be connected to the first ferroelectric capacitor CFE1 of each of the plurality of memory cells UMC arranged in columns and rows in the first horizontal direction (X direction) and the second horizontal direction (Y direction), the second word line WL2 may be connected to the second ferroelectric capacitor CFE2 of each of the plurality of memory cells UMC arranged in columns and rows in the first horizontal direction (X direction) and the second horizontal direction (Y direction), and the third word line WL3 may be connected to the third ferroelectric capacitor CFE3 of each of the plurality of memory cells UMC arranged in columns and rows in the first horizontal direction (X direction) and the second horizontal direction (Y direction). Although FIG. 1 illustrates that a plurality of word lines WL extend in the first horizontal direction (X direction), this is for convenience of illustration, and the plurality of word lines WL may have a plate shape and extend in the first horizontal direction (X direction) and the second horizontal direction (Y direction).

Each of the plurality of ferroelectric capacitors CFE has positive polarization and negative polarization. The voltage applied to the gate of the second transistor ST may vary depending on the polarization direction of each of the plurality of ferroelectric capacitors CFE included in one memory cell UMC. For example, when one memory cell UMC includes the first ferroelectric capacitor CFE1, the second ferroelectric capacitor CFE2, and the third ferroelectric capacitor CFE3, there may be four states: three positive polarizations, two positive polarizations and one negative polarization, one positive polarization and two negative polarizations, and three negative polarizations, and accordingly, one memory cell UMC may store information of 2 bits. By increasing the number of ferroelectric capacitors CFE included in one memory cell UMC, information of 3 or more bits may be stored in one memory cell UMC.

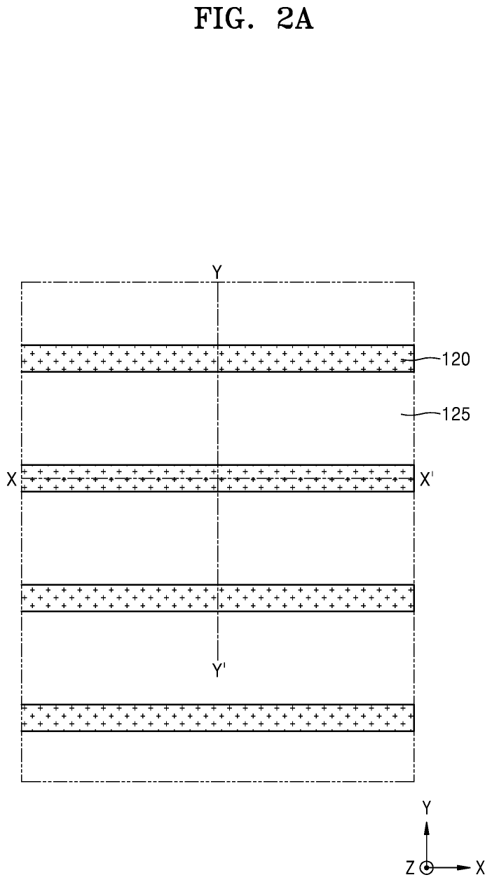

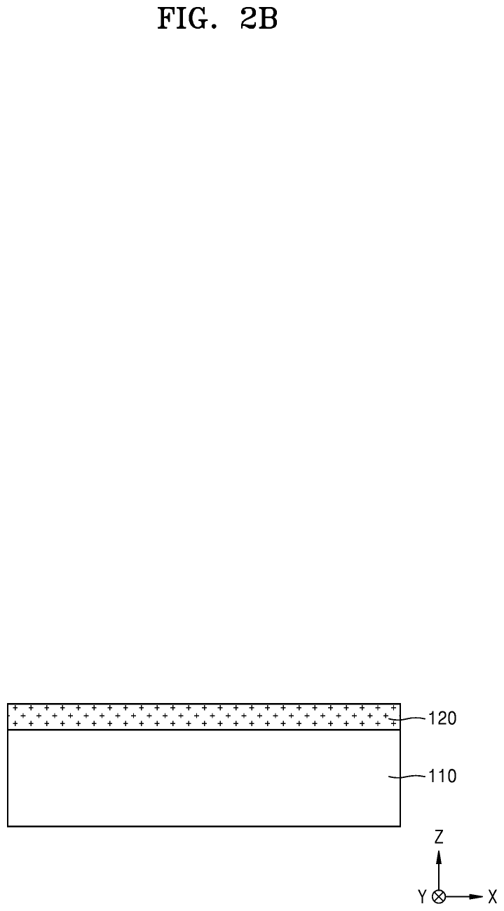

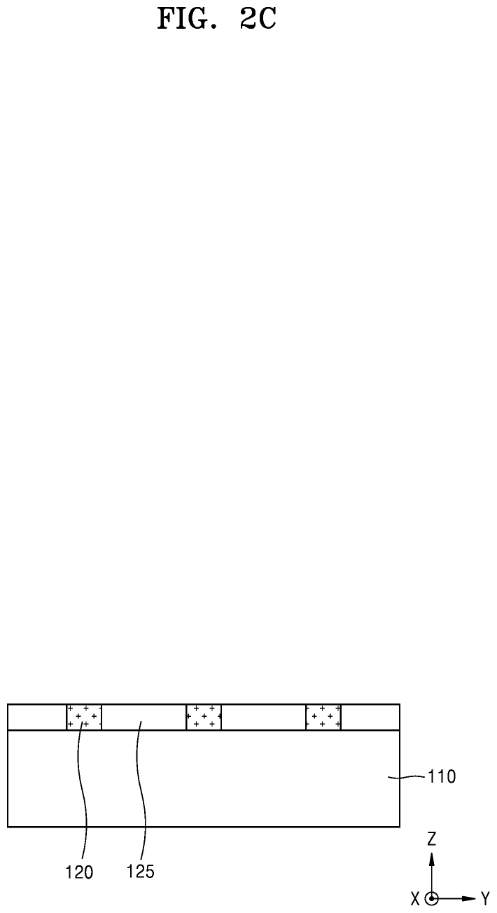

FIGS. 2A through 18C are diagrams illustrating a process sequence of a method of manufacturing a semiconductor memory device according to some implementations; and FIGS. 19A through 19C are diagrams of a semiconductor memory device 1. Each of FIGS. 2A, 3A, 4A, 5A, 6A, 7A, 8A, 9A, 10A, 11A, 12A, 13A, 14A, 15A, 16A, 17A, 18A, and 19A may be a plan view of a semiconductor memory device according to some implementations, each of FIGS. 2B, 3B, 4B, 5B, 6B, 7B, 8B, 9B, 10B, 11B, 12B, 13B, 14B, 15B, 16B, 17B, 18B, and 19B may be a cross-sectional view taken along line X-X′ in FIGS. 2A, 3A, 4A, 5A, 6A, 7A, 8A, 9A, 10A, 11A, 12A, 13A, 14A, 15A, 16A, 17A, 18A, and 19A, and each of FIGS. 2C, 3C, 4C, 5C, 6C, 7C, 8C, 9C, 10C, 11C, 12C, 13C, 14C, 15C, 16C, 17C, 18C, and 19C may be a cross-sectional view taken along line Y-Y′ in FIGS. 2A, 3A, 4A, 5A, 6A, 7A, 8A, 9A, 10A, 11A, 12A, 13A, 14A, 15A, 16A, 17A, 18A, and 19A.

Referring to FIGS. 2A through 2C together, a plurality of first conductive lines 120 and a base insulating layer 125 surrounding the plurality of first conductive lines 120 are formed on a substrate 110. For example, the substrate 110 may include silicon (Si), such as crystalline Si, polycrystalline Si, or amorphous Si. Alternatively, the substrate 110 may include at least one compound semiconductor of a semiconductor element such as germanium (Ge), silicon germanium (SiGe), silicon carbide (SiC), gallium arsenide (GaAs), indium arsenide (InAs), and indium phosphide (InP). Alternatively, the substrate 110 may include a silicon-on-insulator (SOI) substrate or a germanium-on-insulator (GEOI) substrate. For example, the substrate 110 may include a buried oxide (BOX) layer. The substrate 110 may include a conductive region, for example, a well doped with impurities, or a structure doped with impurities. The substrate 110 may further include a semiconductor material included in the substrate 110 and an insulating material arranged in at least a portion between the plurality of first conductive lines 120. For example, the insulating material may include silicon oxide, silicon nitride, silicon oxynitride, or a combination thereof.

The plurality of first conductive lines 120 may extend in parallel with each other in the first horizontal direction (X direction). The plurality of first conductive lines 120 may be arranged at equal intervals in the second horizontal direction (Y direction). The first conductive line 120 may include the bit line BL illustrated in FIG. 1. The base insulating layer 125 may be arranged between the plurality of first conductive lines 120. In some embodiments, the upper surface of each of the base insulating layer 125 and the plurality of first conductive lines 120 may be at the same vertical level to form a coplanar surface.

In some implementations, each of the plurality of first conductive lines 120 includes a conductive barrier layer and a conductive charging layer covering the conductive barrier layer. The conductive barrier layer may include, for example, metal, conductive metal nitride, conductive metal silicide, or a combination thereof. For example, the conductive barrier layer may include TiN. The conductive charging layer may include, for example, doped polysilicon, Ru, RuO, Pt, PtO, Ir, IrO, SrRuO (SRO), (Ba,Sr)RuO (BSRO), CaRuO (CRO), BaRuO, La(Sr,Co)O, Ti, TiN, W, WN, Ta, TaN, TiAlN, TiSiN, TaAlN, TaSiN, or a combination thereof. For example, the base insulating layer 125 may include silicon oxide or an insulating material having a lower dielectric constant than silicon oxide.

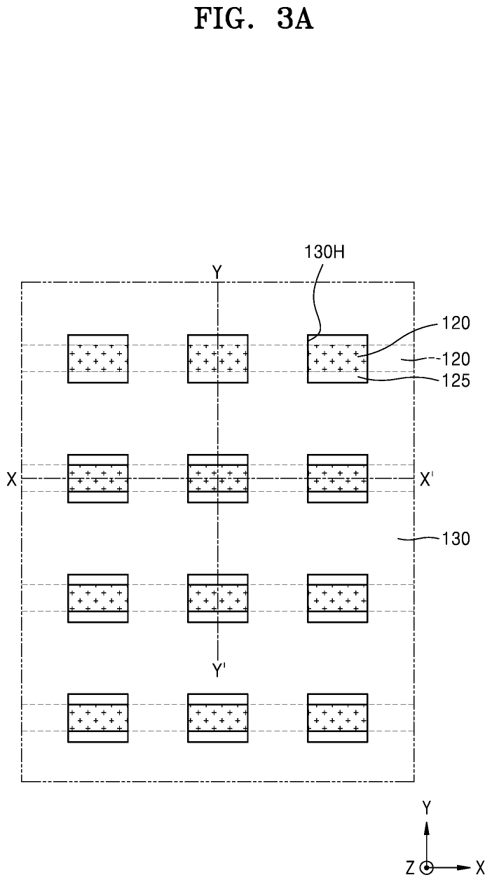

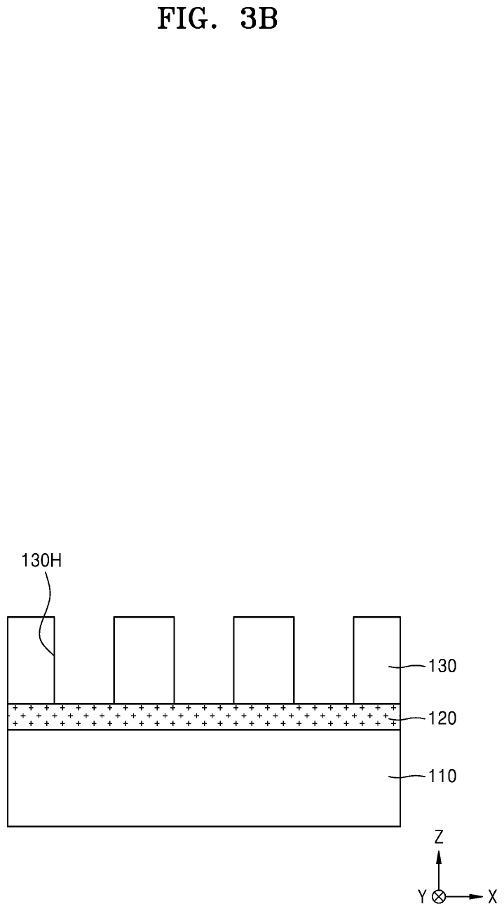

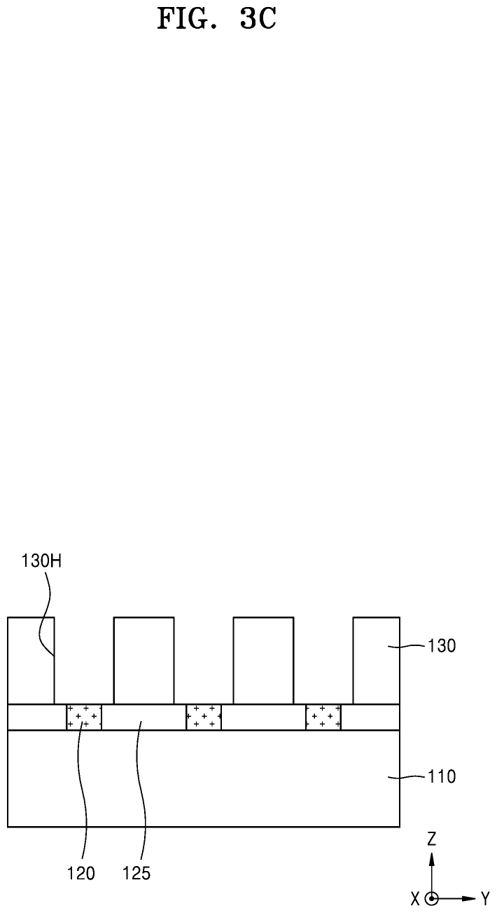

Referring to FIGS. 3A through 3C together, a first interlayer insulating layer 130 is formed on the base insulating layer 125 and the plurality of first conductive lines 120. The first interlayer insulating layer 130 may include silicon oxide or an insulating material having a lower dielectric constant than silicon oxide. The first interlayer insulating layer 130 may include a plurality of first holes 130H. The plurality of first holes 130H may penetrate the first interlayer insulating layer 130 from an upper surface to a bottom surface thereof.

The plurality of first holes 130H are arranged in columns and rows in the first horizontal direction (X direction) and the second horizontal direction (Y direction). For example, the plurality of first holes 130H may be apart from each other along the plurality of first conductive lines 120 extending in the first horizontal direction (X direction). The horizontal width in the second horizontal direction (Y direction) of each of the plurality of first holes 130H may be equal to or greater than the horizontal width in the second horizontal direction (Y direction) of each of the plurality of first conductive lines 120. Portions of the plurality of first conductive lines 120 may be exposed at the bottom surface of the plurality of first holes 130H. In some implementations, portions of the base insulating layer 125 may be exposed on the bottom surface of the plurality of first holes 130H together with portions of the plurality of first conductive lines 120. The horizontal width in the first horizontal direction (X direction) of each of the plurality of first holes 130H may be generally equal to or greater than the horizontal width in the second horizontal direction (Y direction) of each of the plurality of first holes 130H. Although FIG. 3A illustrates that the horizontal cross-section of the plurality of first holes 130H has a rectangular shape, the implementations are not limited thereto. For example, the horizontal cross-section of the plurality of first holes 130H may have a square, a rectangle, a circle, an oval, or a polygonal shape with four or more sides.

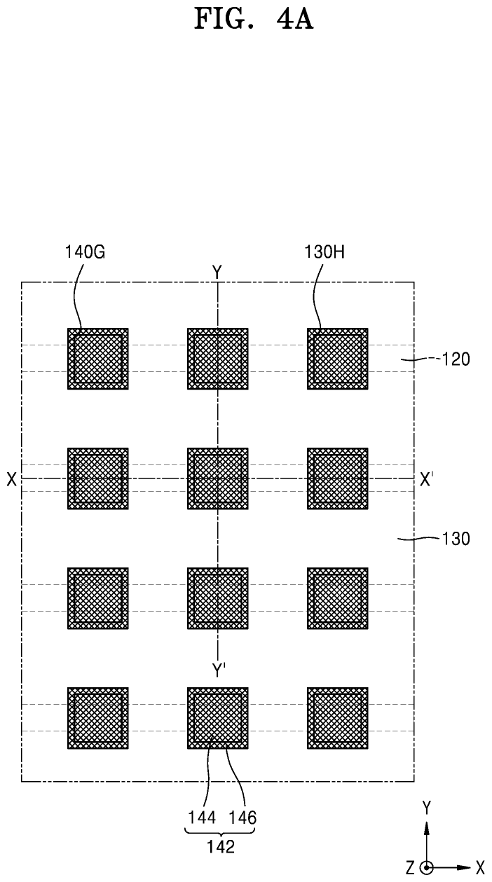

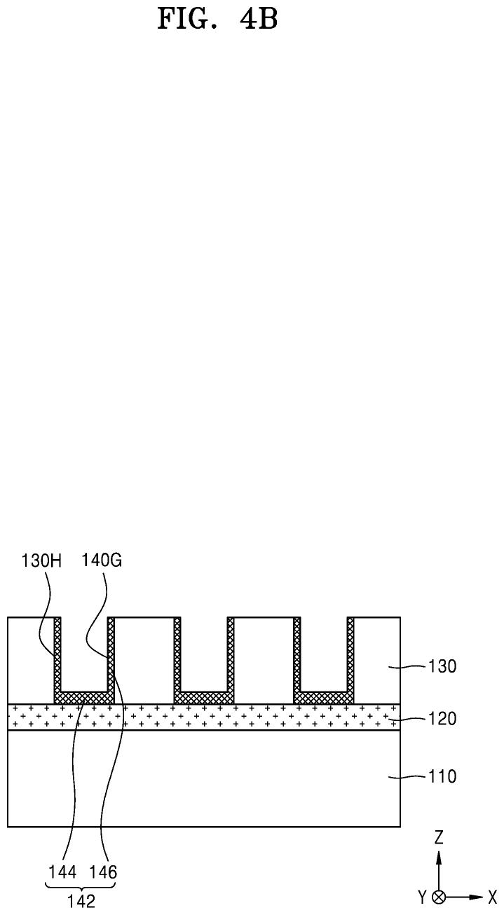

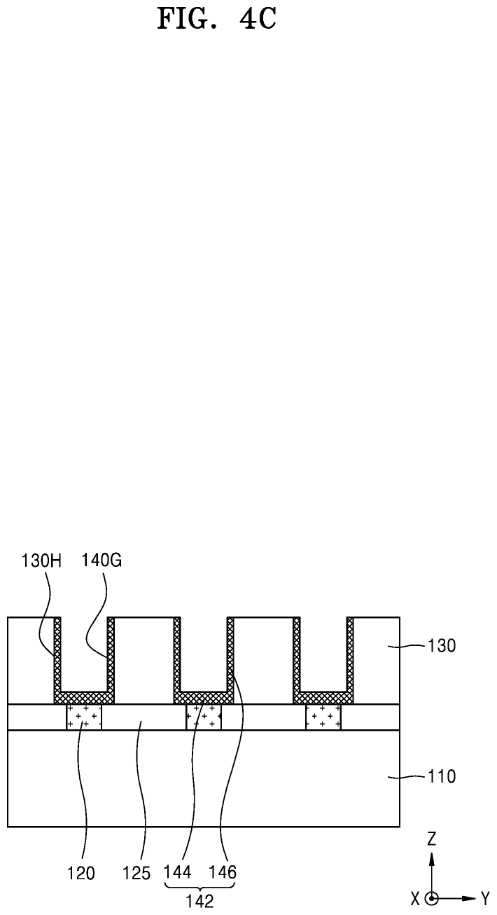

Referring to FIGS. 4A through 4C together, a plurality of first channel material layers 142 covering inner surfaces and bottom surfaces of the plurality of first holes 130H are formed. The first channel material layer 142 may include a semiconductor material, a two-dimensional (2D) semiconductor material, or an oxide semiconductor material. The semiconductor material may include Si, Ge, or SiGe. The 2D semiconductor material may include molybdenum oxide (MoS₂), tungsten diselenide (WSe₂), graphene, carbon nano tube, or a combination thereof. The oxide semiconductor material may include InₓGa_{y}Zn_{z}O, InₓGa_{y}Si_{z}, InₓSn_{y}Zn_{z}O, InₓZn_{y}O, ZnₓO, ZnₓSn_{y}O, ZnₓO_{y}N, ZrₓZn_{y}Sn_{z}, SnₓO, HfₓIn_{y}Zn_{z}, GaₓZn_{y}Sn_{z}, AlₓZn_{y}Sn_{z}O, YbₓGa_{y}Zn_{z}, InₓGa_{y}O, or a combination thereof.

The plurality of first channel material layers 142 may cover the first interlayer insulating layer 130 on the inner surfaces of the plurality of first holes 130H, and on the bottom surfaces of the plurality of first holes 130H, may cover the first conductive line 120 or the first conductive line 120 and the base insulating layer 125. For example, the plurality of first channel material layers 142 may conformally cover the inner surfaces and the bottom surfaces of the plurality of first holes 130H. Each of the plurality of first channel material layers 142 may include a first bottom surface portion 144 covering the bottom surface of each of the plurality of first holes 130H and a first sidewall portion 146 covering the inner surface of each of the plurality of first holes 130H. The first bottom surface portion 144 may be in contact with the first conductive line 120, and the first sidewall portion 146 may be in contact with the first interlayer insulating layer 130.

The plurality of first channel material layers 142 may be formed not to fill all of the plurality of first holes 130H. A plurality of first limited spaces 140G may be limited inside the plurality of first holes 130H by the plurality of first channel material layers 142.

The plurality of first channel material layers 142 may cover the inner surfaces and the bottom surfaces of the plurality of first holes 130H, form a first preliminary material layer covering the upper surface of the first interlayer insulating layer 130, and then have a portion of the first preliminary material layer covering the upper surface of the first interlayer insulating layer 130 removed.

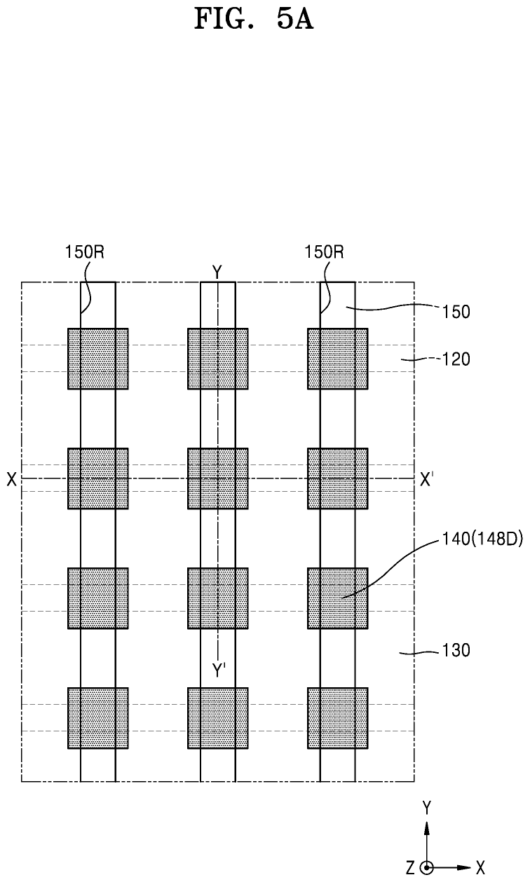

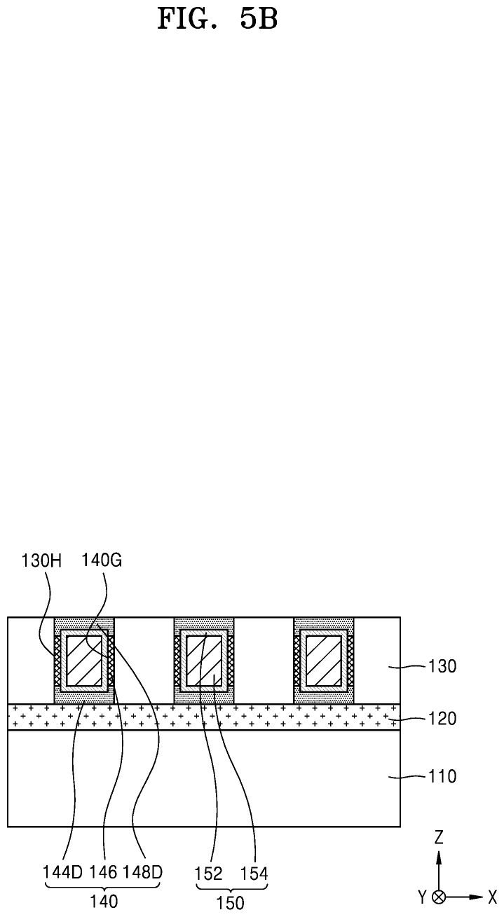

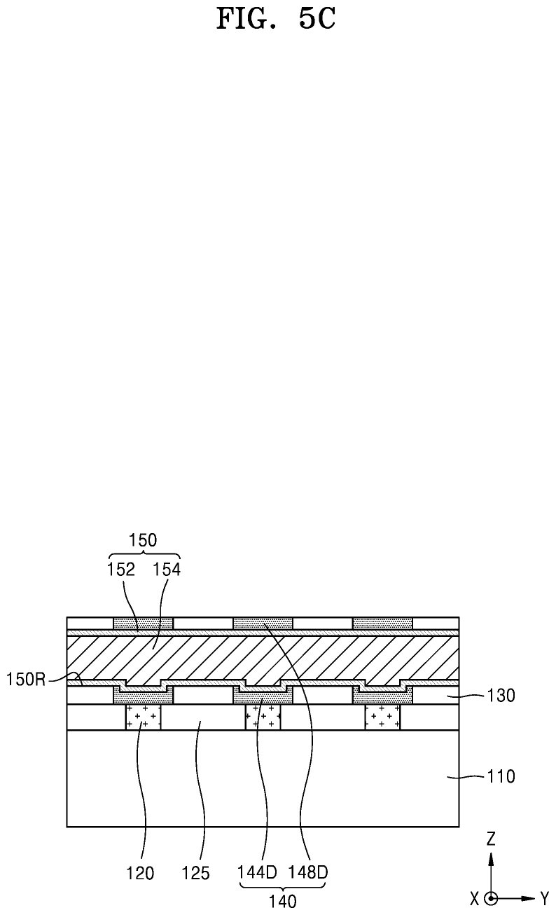

Referring to FIGS. 4A through 4C and 5A through 5C together, by injecting impurities into the first bottom surface portion 144 of the first channel material layer 142, a first impurity region 144D is formed. For example, by injecting an n-type impurity to the first bottom surface portion 144 of the first channel material layer 142, the first impurity region 144D, which is an n-type region, may be formed.

After a plurality of recess spaces 150R extending in the second horizontal direction (Y direction) are formed by removing portions of the first interlayer insulating layer 130 arranged between the first limited spaces 140G, which are arranged in the second horizontal direction (Y direction) among the plurality of first limited spaces 140G, a first gate structure 150 filling each of the plurality of recess spaces 150R and a second impurity region 148D covering the first gate structure 150 are formed. The first impurity region 144D, the first sidewall portion 146, and the second impurity region 148D may constitute a first channel structure 140. The first sidewall portion 146 may also be referred to as a first channel region 146. The first gate structure 150 may include a first gate electrode 154 and a first gate insulating layer 152 surrounding the first gate electrode 154. The first gate insulating layer 152 may be arranged between the first channel structure 140 and the first gate electrode 154. In some implementations, the first gate insulating layer 152 may generally have the same thickness between the first channel structure 140 and the first gate electrode 154, and may surround the first gate electrode 154. The first gate electrode 154 may include the control line CL illustrated in FIG. 1. A plurality of first gate electrodes 154 may extend in parallel with each other in the second horizontal direction (Y direction). A plurality of first gate electrodes 154 may be arranged at an equal interval in the first horizontal direction (X direction).

Each of the plurality of first gate electrodes 154 includes a doped semiconductor material, a metal material, a conductive metal nitride, or a combination thereof. For example, each of the plurality of first gate electrodes 154 may include doped polysilicon, Ti, TiN, Ta, TaN, W, WN, TiSiN, WSiN, or a combination thereof. Each of the plurality of first gate insulating layers 152 may include at least one of silicon oxide, silicon nitride, silicon oxynitride, oxide/nitride/oxide (ONO), a high-k dielectric film having a higher dielectric constant than silicon oxide, and a ferroelectric. For example, each of a plurality of first gate insulating layers 152 may have a dielectric constant of about 10 to about 25. In some implementations, each of the plurality of first gate insulating layers 152 may have a stacked structure of a first dielectric layer including silicon oxide and a second dielectric layer including at least one of a high dielectric material and a ferroelectric. For example, a high dielectric material and a ferroelectric may include at least one of hafnium oxide (HfO), hafnium silicate (HfSiO), hafnium oxynitride (HfON), hafnium silicon oxynitride (HfSiON), or lanthanum oxide (LaO), lanthanum aluminum oxide (LaAIO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium tantalum oxide bismuth (STB), bismuth ferrous oxide (BFO), strontium titanium oxide (SrTiO), yttrium oxide (YO), aluminum oxide (AlO), and lead scandium tantalum oxide (PbScTaO).

In some implementations, the second impurity region 148D may include the same material as the first channel material layer 142. For example, the second impurity region 148D may include an n-type region into which an n-type impurity has been injected. In some implementations, the upper surface of the first interlayer insulating layer 130, and the upper surface of the first channel structure 140, that is, the upper surface of the second impurity region 148D, may be at the same vertical level to be coplanar.

In some implementations, bottom surfaces of the plurality of recess spaces 150R may have steps. For example, the bottom surfaces of portions of the plurality of recess spaces 150R overlapping the plurality of first limited spaces 140G may be at a lower vertical level than the bottom surfaces of the remaining portions thereof. For example, the plurality of first channel region 146 and the plurality of first gate electrodes 154 included in the plurality of first gate structures 150 may have a structure protruding downward at portions, where the plurality of first gate structures 150 and the plurality of first gate electrodes 154 respectively overlap the plurality of first limited spaces 140G, that is, portions on the first impurity region 144D. The upper surfaces of the plurality of first gate structures 150 and the plurality of first gate electrodes 154 included in the plurality of first gate structures 150 may be generally at the same vertical level.

In FIGS. 5A through 5C, the first gate structure 150 is illustrated to have an inner gate structure, but the implementations are not limited thereto, and the first gate structure 150 may have various structures, such as a gate all-around (GAA) structure, a single gate structure, and a mirror symmetry single gate structure.

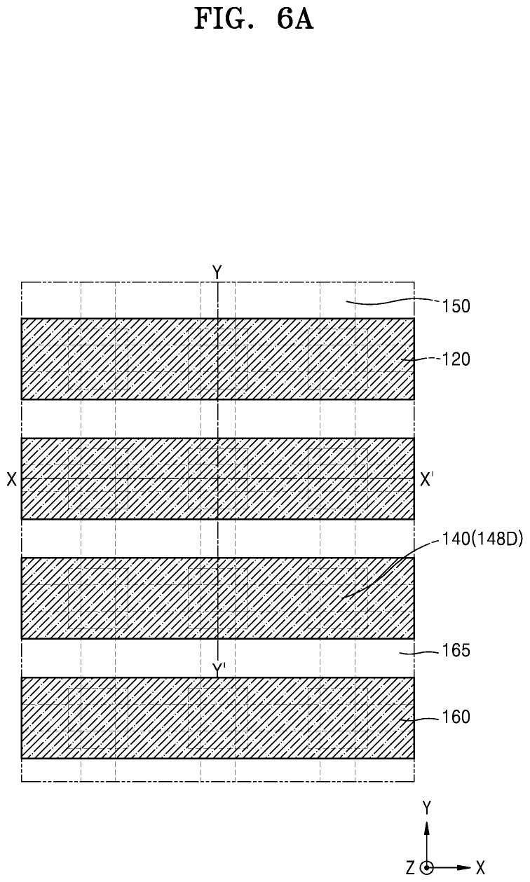

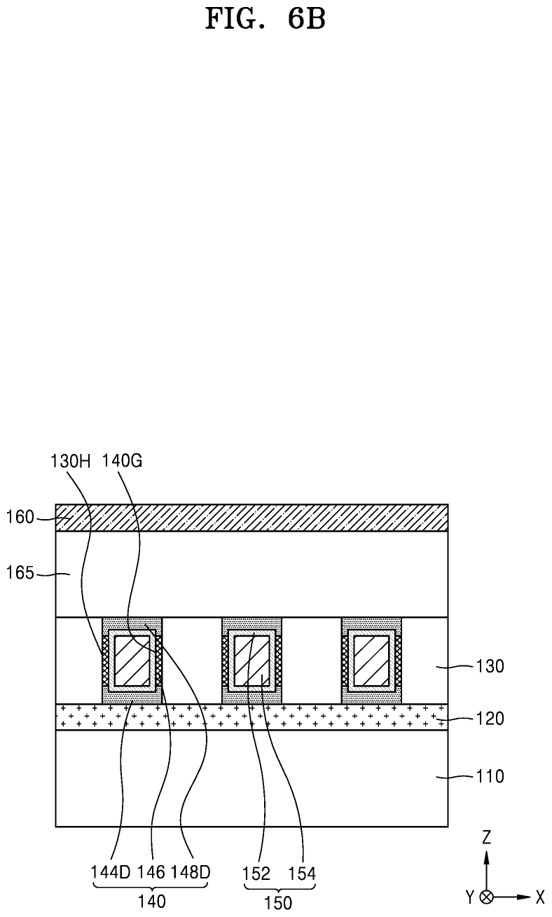

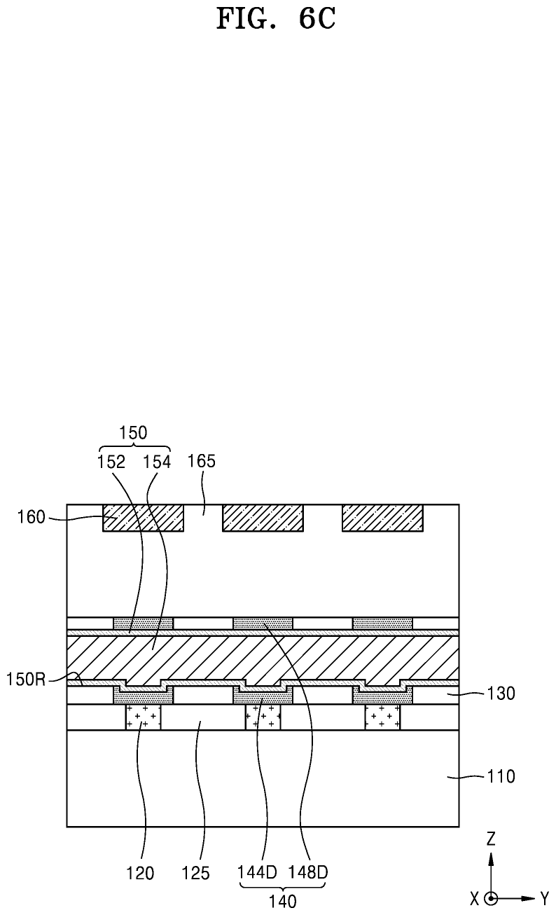

Referring to FIGS. 6A through 6C, a plurality of second conductive lines 160 above the first interlayer insulating layer 130, the first channel structure 140, and the plurality of first gate structures 150, and a second interlayer insulating layer 165 covering the first interlayer insulating layer 130, the first channel structure 140, and the plurality of first gate structures 150 and surrounding the plurality of second conductive lines 160 are formed. The plurality of second conductive lines 160 including the second interlayer insulating layer 165 therebetween may be apart from the first channel structure 140 and the plurality of first gate structures 150 in the vertical direction (Z direction).

The plurality of second conductive lines 160 may extend in parallel with each other in the first horizontal direction (X direction). A plurality of second conductive lines 160 may be arranged at equal intervals in the second horizontal direction (Y direction). The second conductive line 160 may include the source line SL illustrated in FIG. 1. The second interlayer insulating layer 165 may be arranged between the plurality of second conductive lines 160. In some implementations, the upper surface of each of the second interlayer insulating layer 165 and the plurality of second conductive lines 160 may be formed at the same vertical level to be coplanar.

In some implementations, each of the plurality of second conductive lines 160 may include a conductive barrier layer and a conductive charging layer covering the conductive barrier layer. The conductive barrier layer may include, for example, metal, conductive metal nitride, conductive metal silicide, or a combination thereof. For example, the conductive barrier layer may include TiN. The conductive charging layer may include, for example, doped polysilicon, Ru, RuO, Pt, PtO, Ir, IrO, SrRuO (SRO), (Ba,Sr)RuO (BSRO), CaRuO (CRO), BaRuO, La(Sr,Co)O, Ti, TiN, W, WN, Ta, TaN, TiAlN, TiSiN, TaAlN, TaSiN, or a combination thereof. For example, the base insulating layer 125 may include silicon oxide or an insulating material having a lower dielectric constant than silicon oxide.

In some implementations, the horizontal width in the second horizontal direction (Y direction) of each of the plurality of second conductive lines 160 may be greater than the horizontal width in the second horizontal direction (Y direction) of each of the plurality of first conductive lines 120.

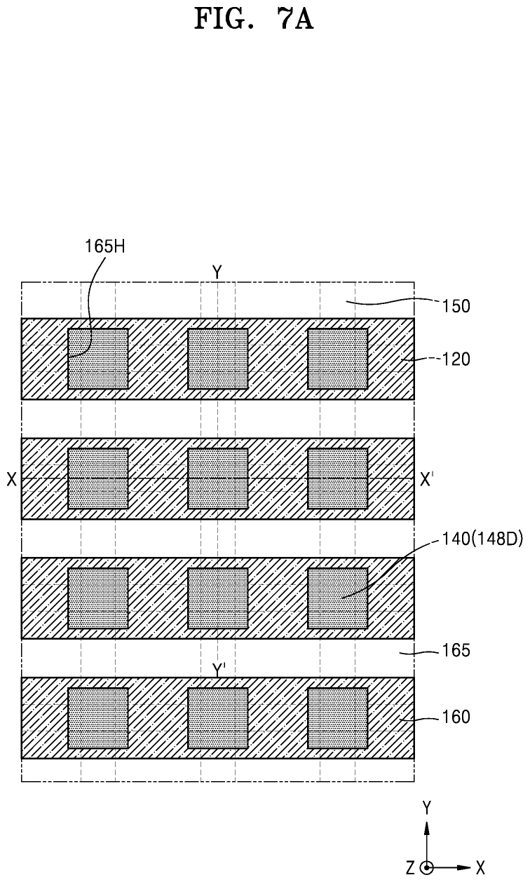

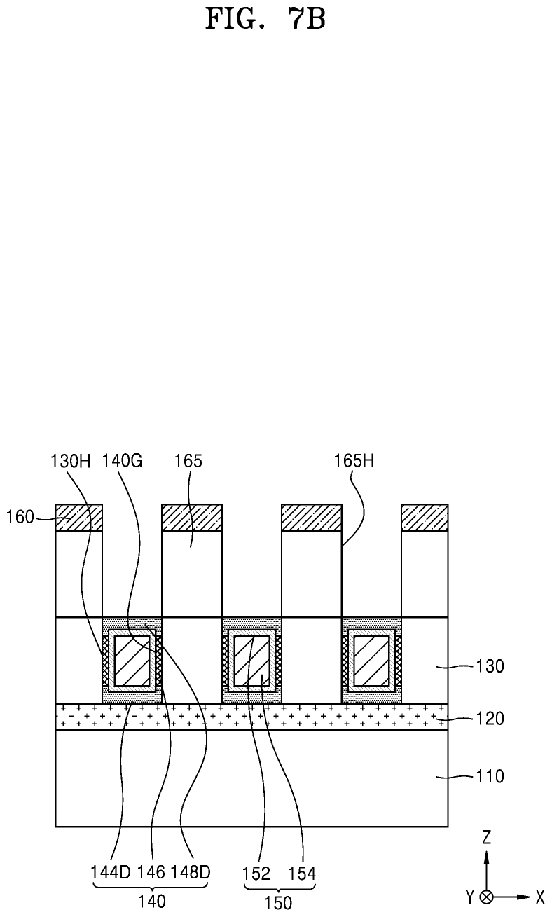

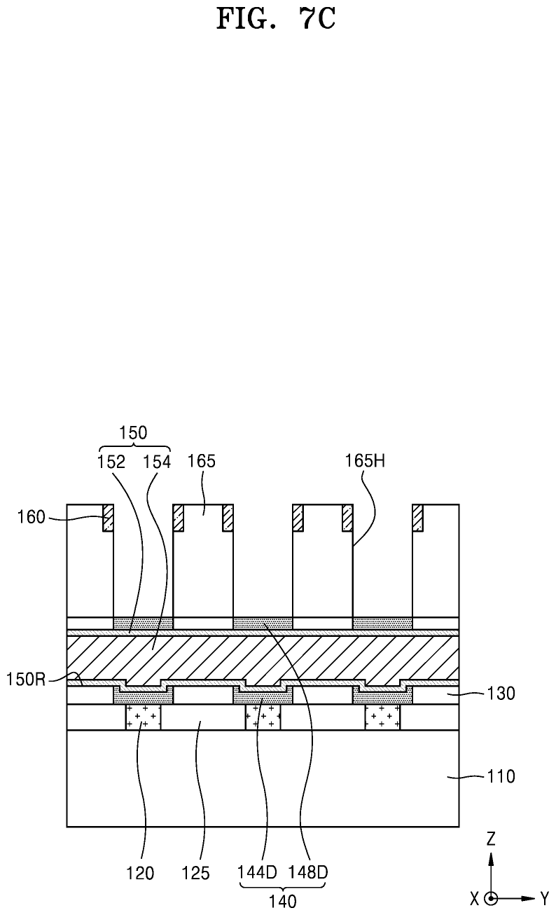

Referring to FIGS. 7A through 7C together, a plurality of second holes 165H penetrating the plurality of second conductive lines 160 and the second interlayer insulating layer 165 are formed. The plurality of second holes 165H may penetrate from an upper surface of the plurality of second conductive lines 160 to a bottom surface of the second interlayer insulating layer 165. The plurality of second holes 165H may be formed to respectively overlap the plurality of first holes 130H in the vertical direction (Z direction). A plurality of first channel structures 140 may be respectively exposed at the bottom surfaces of the plurality of second holes 165H. For example, the second impurity region 148D of each of the plurality of first channel structures 140 may be exposed at the bottom surface of each of the plurality of second holes 165H.

The plurality of second holes 165H may respectively penetrate the plurality of second conductive lines 160 but may be formed to be arranged inside the plurality of second conductive lines 160 in a plan view so that each of the plurality of second conductive lines 160 is not cut. For example, the horizontal width in the second horizontal direction (Y direction) of each of the plurality of second holes 165H may be less than the horizontal width in the second horizontal direction (Y direction) of each of the plurality of second conductive lines 160. In a plan view, the plurality of second holes 165H may be respectively and completely surrounded by the plurality of second conductive lines 160.

The plurality of second holes 165H may be arranged in columns and rows in the first horizontal direction (X direction) and the second horizontal direction (Y direction). For example, the plurality of second holes 165H may be apart from each other along the plurality of second conductive lines 160 extending in the first horizontal direction (X direction). The horizontal width in the second horizontal direction (Y direction) of each of the plurality of second holes 165H may be generally equal to the horizontal width in the second horizontal direction (Y direction) of each of the plurality of first holes 130H. The horizontal width in the first horizontal direction (X direction) of each of the plurality of second holes 165H may be generally equal to the horizontal width in the second horizontal direction (Y direction) of each of the plurality of second holes 165H. Although FIG. 7A illustrates that the horizontal cross-section of the plurality of second holes 165H has a rectangular shape, the implementations are not limited thereto. For example, the horizontal cross-section of the plurality of second holes 165H may have a square, a rectangle, a circle, an oval, or a polygonal shape with four or more sides.

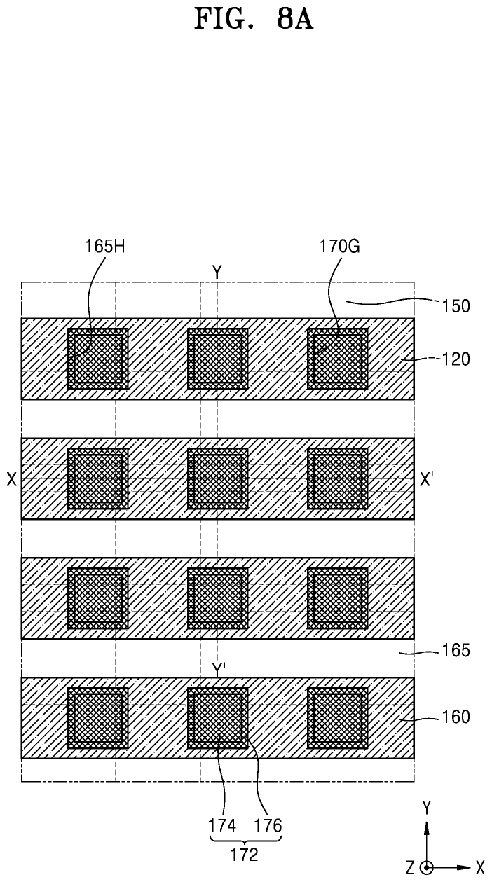

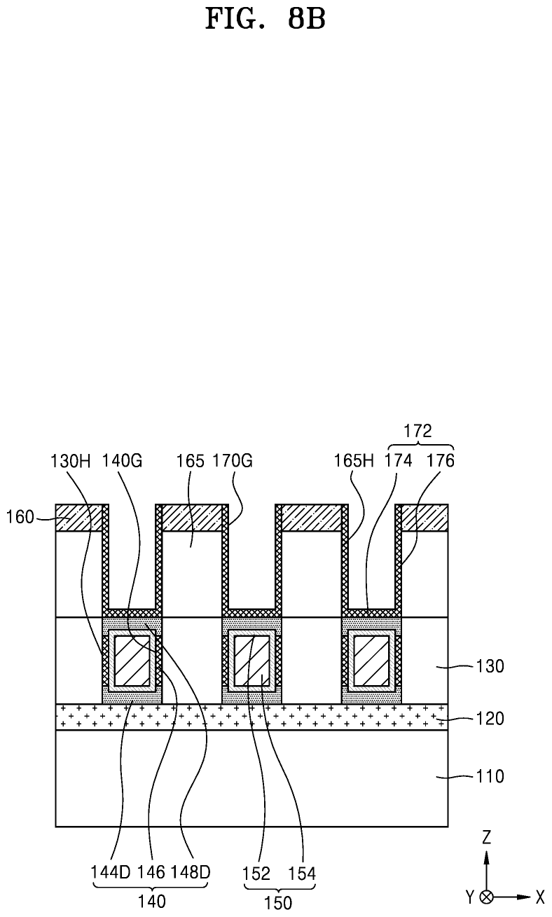

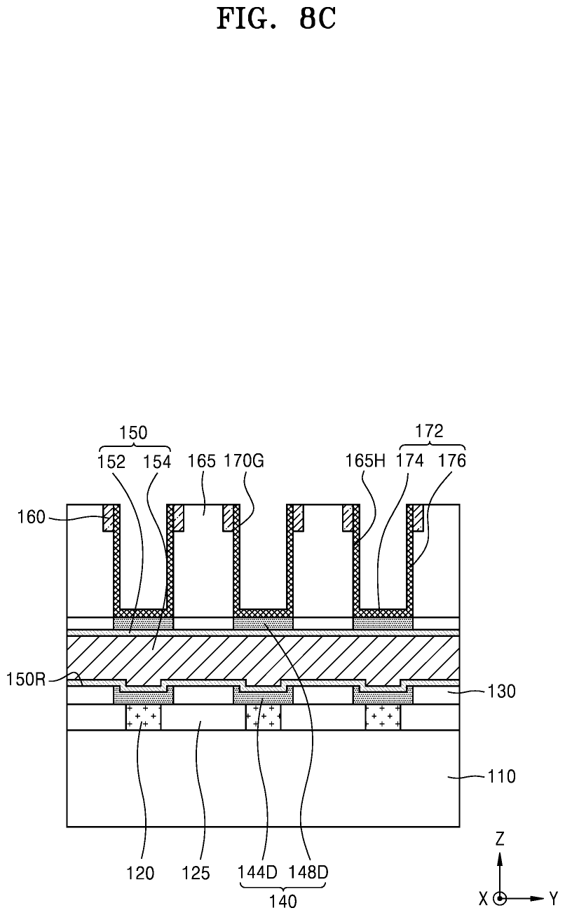

Referring to FIGS. 8A through 8C together, a plurality of second channel material layers 172 covering inner surfaces and bottom surfaces of the plurality of second holes 165H are formed. The second channel material layer 172 may include a semiconductor material, a 2D semiconductor material, or an oxide semiconductor material.

The plurality of second channel material layers 172 may cover the plurality of second conductive lines 160 and the plurality of second interlayer insulating layers 165 on the inner surfaces of the plurality of second holes 165H, respectively, and may cover the plurality of second impurity regions 148D of the plurality of first channel structures 140 on the bottom surfaces of the plurality of second holes 165, respectively. For example, the plurality of second channel material layer 172 may respectively and conformally cover the inner surfaces and the bottom surfaces of the plurality of second holes 165H. Each of the plurality of second channel material layers 172 may include a second bottom surface portion 174 covering the bottom surface of each of the plurality of second holes 165H and a second sidewall portion 176 covering the inner surface of each of the plurality of second holes 165H. The second bottom surface portion 174 may be in contact with the second impurity region 148D of the first channel structure 140, and the second sidewall portion 176 may be in contact with the second conductive line 160 and the second interlayer insulating layer 165.

The plurality of second channel material layers 172 may be formed not to fill all of the plurality of second holes 165H. A plurality of second limited spaces 170G may be limited in the plurality of second holes 165H by the plurality of second channel material layers 172.

After a second preliminary material layer covering the inner side surfaces and bottom surfaces of the plurality of second holes 165H and covering upper surfaces of the plurality of second conductive lines 160 and the second interlayer insulating layer 165 is formed, the plurality of second channel material layers 172 are formed by removing a portion of the second preliminary material layer covering the upper surfaces of the plurality of second conductive lines 160 and the second interlayer insulating layer 165.

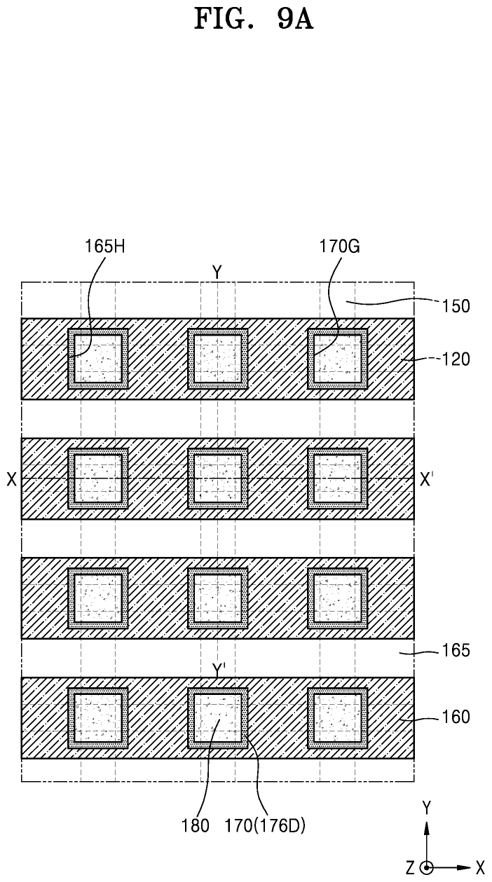

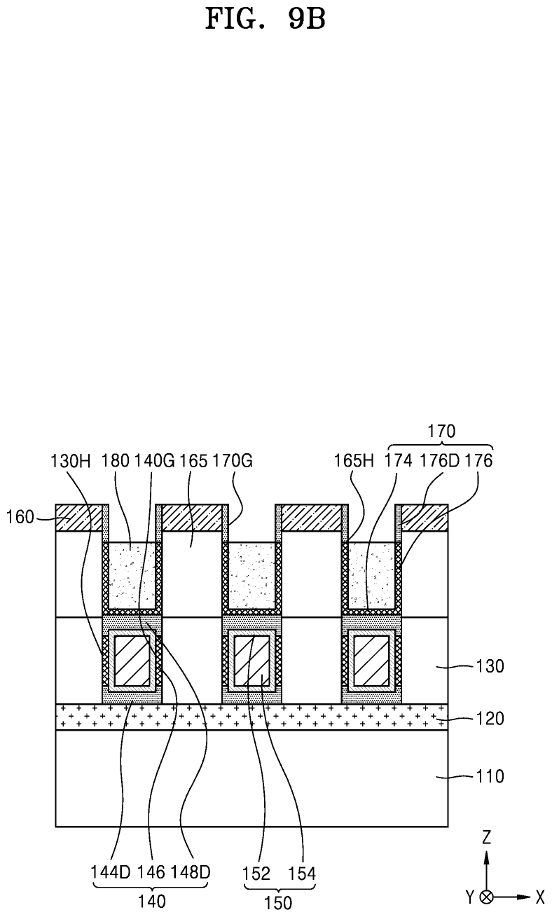

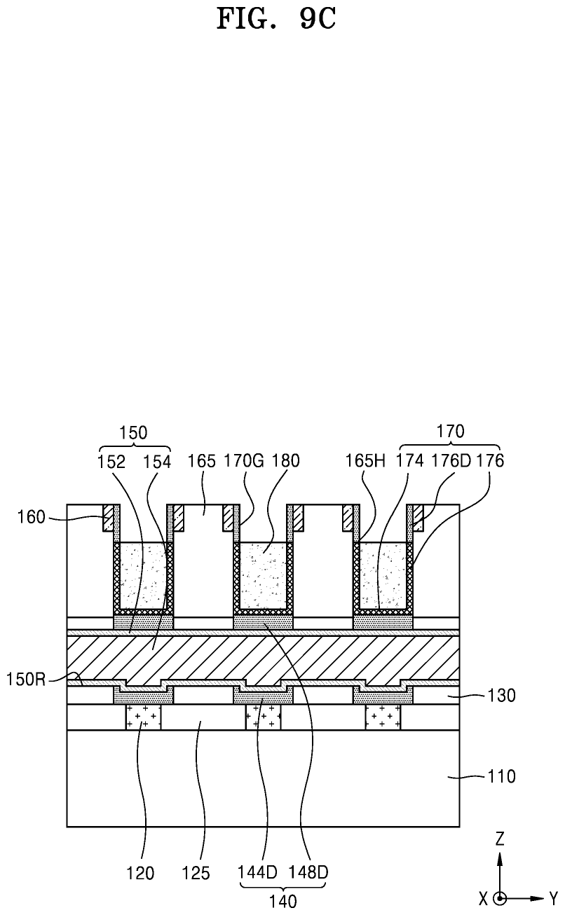

Referring to FIGS. 8A through 8C and 9A through 9C together, a plurality of first sacrificial layers 180 filling lower side portions of the plurality of second limited spaces 170G are formed.

Each of the plurality of first sacrificial layers 180 may not cover an upper side portion of the second sidewall portion 176 of each of the plurality of second channel material layers 172. For example, the plurality of first sacrificial layers 180 may include a spin-on hard mask (SOH) material, but are not limited thereto. After a first sacrificial material layer filling the plurality of second limited spaces 170G and covering the upper surfaces of the plurality of second conductive lines 160 and the second interlayer insulating layer 165 is formed, the plurality of first sacrificial layers 180 may be formed by removing a portion of the first sacrificial material layer covering the upper surfaces of the plurality of second conductive lines 160 and the second interlayer insulating layer 165 and filling upper side portions of the plurality of second limited spaces 170G.

A third impurity region 176D is formed by injecting impurities into upper side portions of the second sidewall portion 176 of each of the plurality of second channel material layers 172, which are not respectively covered by the plurality of first sacrificial layers 180. In some implementations, the third impurity region 176D may include an n-type region into which an n-type impurity has been injected. The second bottom surface portion 174, the second sidewall portion 176, and the third impurity region 176D may constitute a second channel structure 170. After a plurality of third impurity regions 176D are formed, the first sacrificial layer 180 may be removed.

In some implementations, during the process of forming the third impurity region 176D, a portion of impurities included in the second impurity region 148D may diffuse into the second bottom surface portion 174, and the second impurity region 148D may expand into the second bottom surface portion 174. For example, the upper surface of the second impurity region 148D may be at a higher vertical level than the upper surface of the first interlayer insulating layer 130. In some implementations, a portion of the impurities included in the second impurity region 148D may diffuse into the second bottom surface portion 174, and all of the second bottom surface portion 174 may also become a portion of the second impurity region 148D.

In some implementations, when all of the second bottom surface portion 174 becomes a portion of the second impurity region 148D, the second sidewall portion 176 may be referred to as a second channel region 176. In some implementations, when all of the second bottom surface portion 174 is not included in a portion of the second impurity region 148D and at least a portion of the second bottom surface portion 174 remains, the second bottom surface portion 174 and the second sidewall portion 176 may be referred to as a second channel region together.

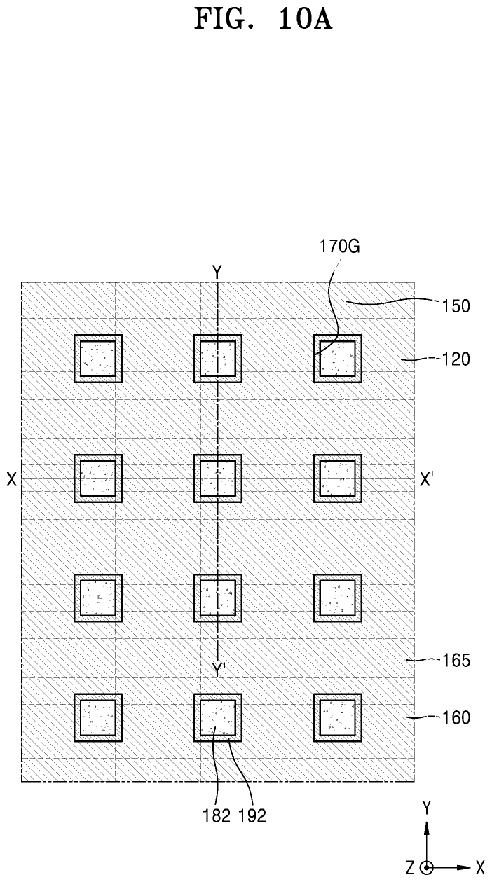

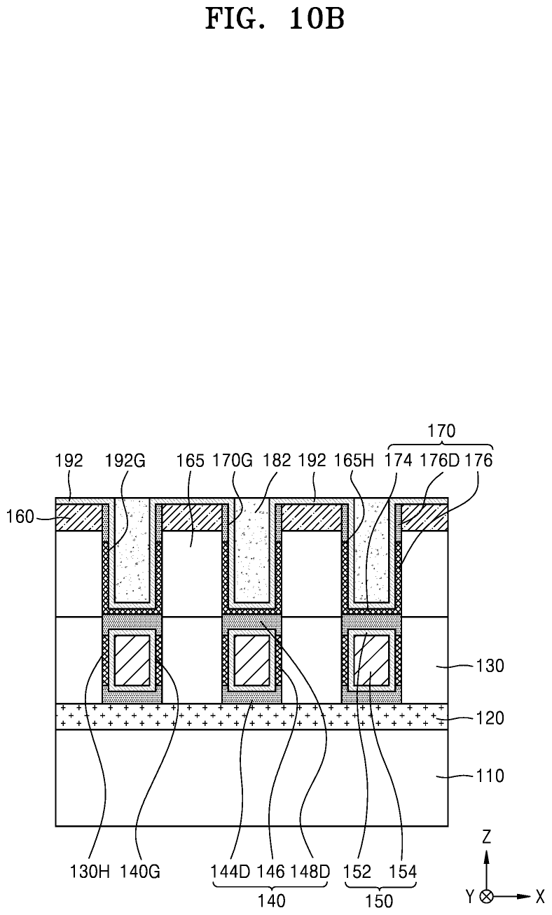

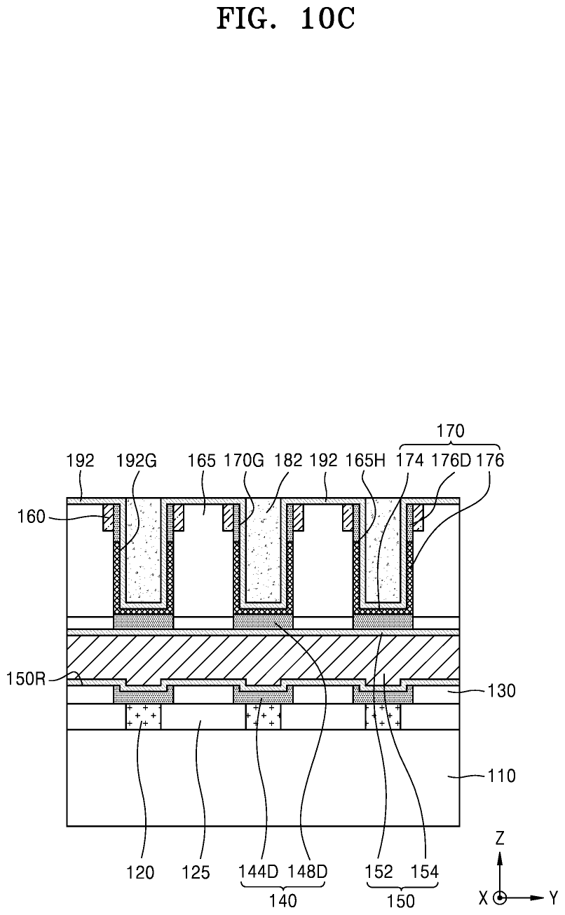

Referring to FIGS. 10A through 10C together, the second gate insulating layer 192 covering the bottom surfaces and inner surfaces of the plurality of second limited spaces 170G, and the upper surfaces of the plurality of second conductive lines 160 and the second interlayer insulating layer 165 is formed. The second gate insulating layer 192 may cover the second channel structure 170 on the bottom surfaces and inner surfaces of the plurality of second limited spaces 170G. The second gate insulating layer 192 may conformally cover the bottom surfaces and inner surfaces of the plurality of second limited spaces 170G, and the upper surfaces of the plurality of second conductive lines 160 and the second interlayer insulating layer 165. A plurality of third limited spaces 192G may be respectively limited in the plurality of second limited spaces 170G by the second gate insulating layer 192.

Each of the plurality of second gate insulating layers 192 may include at least one of silicon oxide, silicon nitride, silicon oxynitride, oxide/nitride/oxide (ONO), a high-k dielectric film having a higher dielectric constant than silicon oxide, and a ferroelectric. For example, each of the plurality of second gate insulating layers 192 may have a dielectric constant of about 10 to about 25. In some implementations, each of the plurality of second gate insulating layers 192 may have a stacked structure of a first dielectric layer including silicon oxide and a second dielectric layer including at least one of a high dielectric material and a ferroelectric.

After the second gate insulating layer 192 is formed, a plurality of second sacrificial layers 182 respectively filling the plurality of third limited spaces 192G are formed. The plurality of second sacrificial layers 182 may respectively fill the plurality of third limited spaces 192G, but may not cover the upper surfaces of the plurality of second conductive lines 160 and the plurality of second interlayer insulating layers 165. For example, the plurality of second sacrificial layers 182 may include the SOH material, but are not limited thereto. After a second sacrificial material layer filling the plurality of third limited spaces 192G and covering the upper surfaces of the plurality of second conductive lines 160 and the plurality of second interlayer insulating layers 165 are formed, the plurality of second sacrificial layers 182 may be formed by removing a portion of the second sacrificial material layer covering the upper surfaces of the plurality of second conductive lines 160 and the plurality of second interlayer insulating layers 165. In some implementations, the uppermost surface of the second gate insulating layer 192, that is, the upper surface a portion of the second gate insulating layer 192 covering the upper surfaces of the plurality of second conductive lines 160 and the plurality of second interlayer insulating layers 165, may be at the same vertical level as the upper surfaces of the plurality of second sacrificial layers 182.

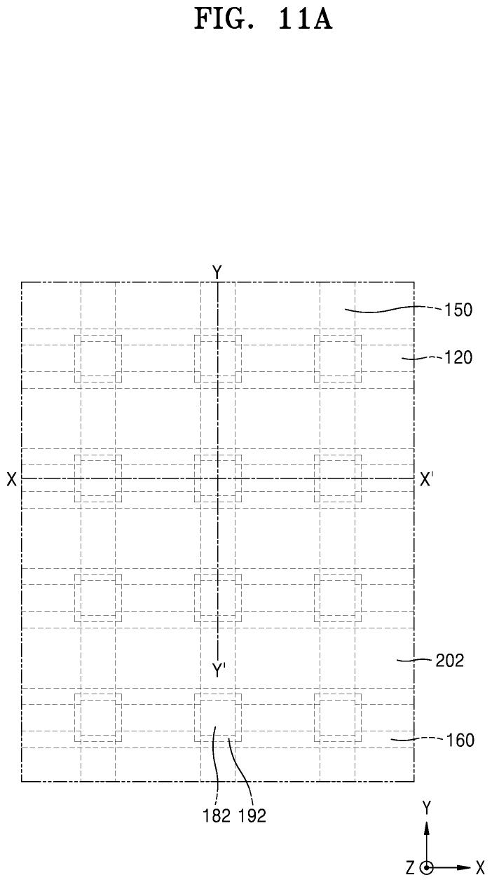

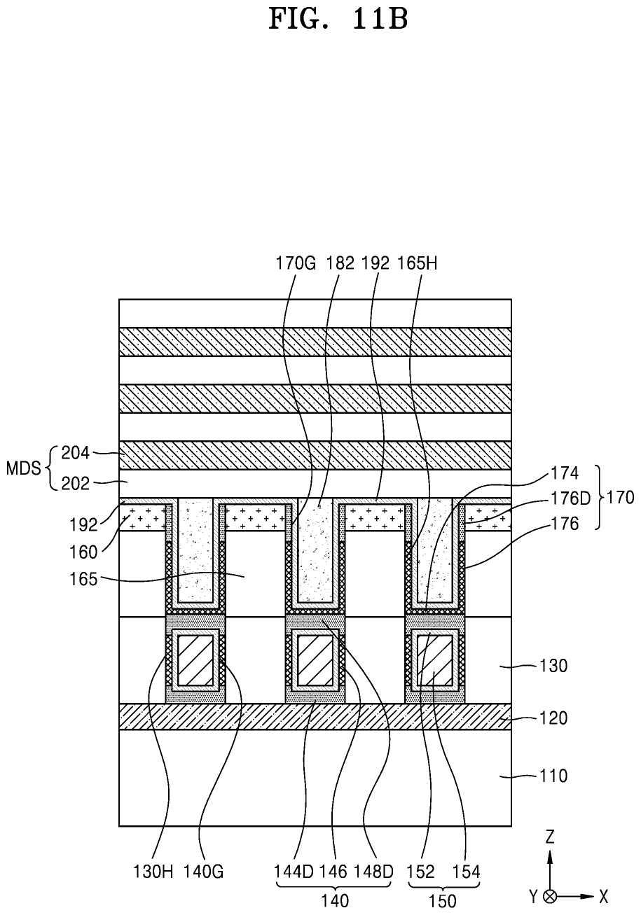

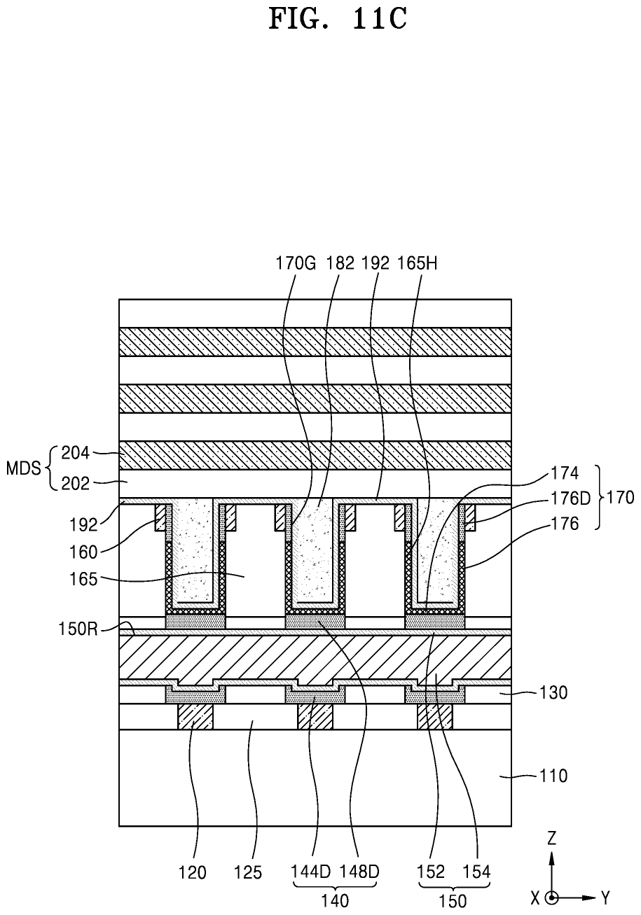

Referring to FIGS. 11A through 11C together, a plurality of insulation layers 202 and a plurality of sacrificial layers 204 are formed on the second gate insulating layer 192 and the plurality of second sacrificial layers 182. Each of the plurality of insulating layers 202 and the plurality of sacrificial layers 204 may be alternately stacked on the second gate insulating layer 192 and the plurality of second sacrificial layers 182. The plurality of insulating layers 202 and the plurality of sacrificial layers 204 may be referred to as a mold structure MDS. Each of the plurality of sacrificial layers 204 may be arranged between two insulating layers 202 adjacent to each other in the vertical direction (Z direction) among the plurality of insulating layers 202. For example, the uppermost end insulating layer 202 among the plurality of insulating layers 202 may cover an upper surface of an uppermost end sacrificial layer 204 among the plurality of sacrificial layer 204, and the lowermost end insulating layer 202 among the plurality of insulating layers 202 may cover a bottom surface of the lowermost end sacrificial layer 204 among the plurality of sacrificial layers 204.

In FIGS. 11A through 11C, the mold structure MDS is illustrated to include four insulating layers 202 and three sacrificial layers 204, but is not limited thereto. For example, the mold structure MDS may also include five or more insulating layers 202 and four or more sacrificial layers 204.

The plurality of insulating layers 202 and the plurality of sacrificial layers 204 may include materials having different etching selectivities from each other. In some implementations, the plurality of insulating layers 202 may include silicon oxide and the plurality of sacrificial layers 204 may include silicon carbide.

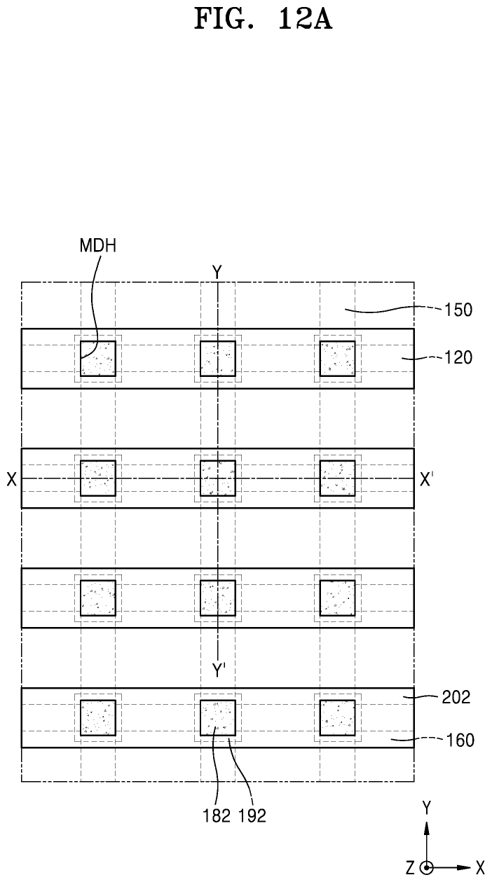

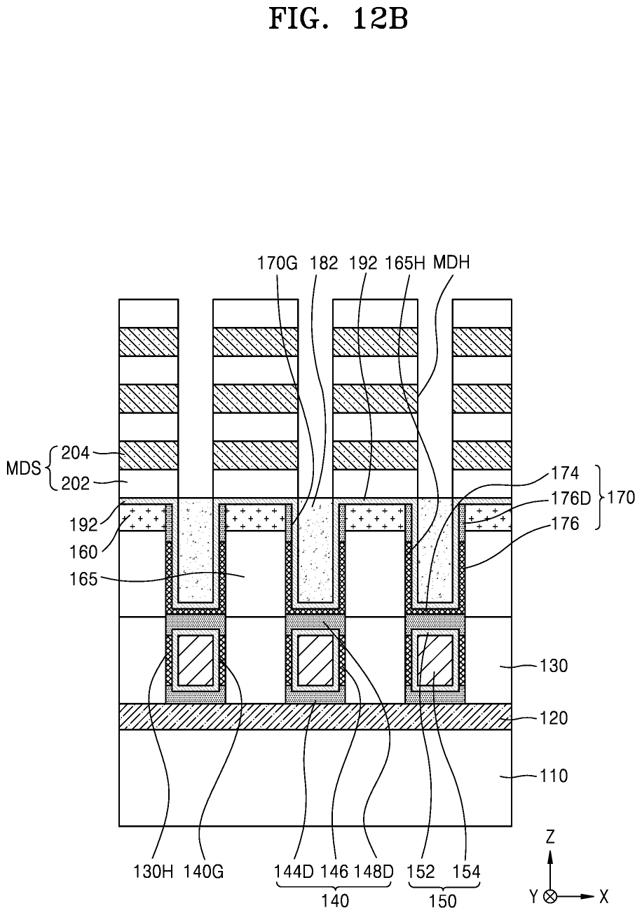

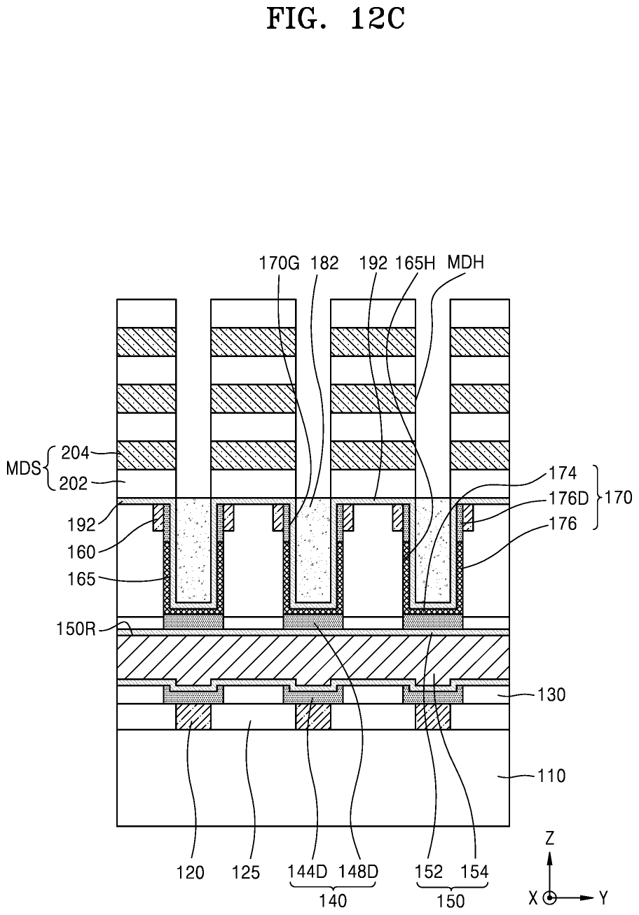

Referring to FIGS. 12A through 12C together, a plurality of third holes MDH penetrating the mold structure MDS are formed. A plurality of third holes MDH penetrate from an upper surface to a lower surface of the mold structure MDS. For example, a plurality of third holes MDH may penetrate both the plurality of insulating layers 202 and the plurality of sacrificial layers 204 included in the mold structure MDS. The plurality of third holes MDH may be formed to overlap respectively the plurality of second holes 165H in the vertical direction (Z direction). The plurality of second sacrificial layers 182 may be exposed at a bottom surface of the plurality of third holes MDH.

The plurality of third holes MDH may be arranged in columns and rows in the first horizontal direction (X direction) and the second horizontal direction (Y direction). For example, the plurality of third holes MDH may be apart from each other along the plurality of second conductive lines 160 extending in the first horizontal direction (X direction). A horizontal width in the second horizontal direction (Y direction) of each of the plurality of third holes MDH may be generally equal to the horizontal width in the second horizontal direction (Y direction) of each of the plurality of second holes 165H. The horizontal width in the first horizontal direction (X direction) of each of the plurality of third holes MDH may be generally equal to the horizontal width in the second horizontal direction (Y direction) of each of the plurality of third holes MDH, but the implementations are not limited thereto. Although FIG. 12A illustrates that a horizontal cross-section of the plurality of third holes MDH has a rectangular shape, the implementations are not limited thereto. For example, the horizontal cross-section of the plurality of third holes MDH may have a square, a rectangle, a circle, an oval, or a polygonal shape with four or more sides.

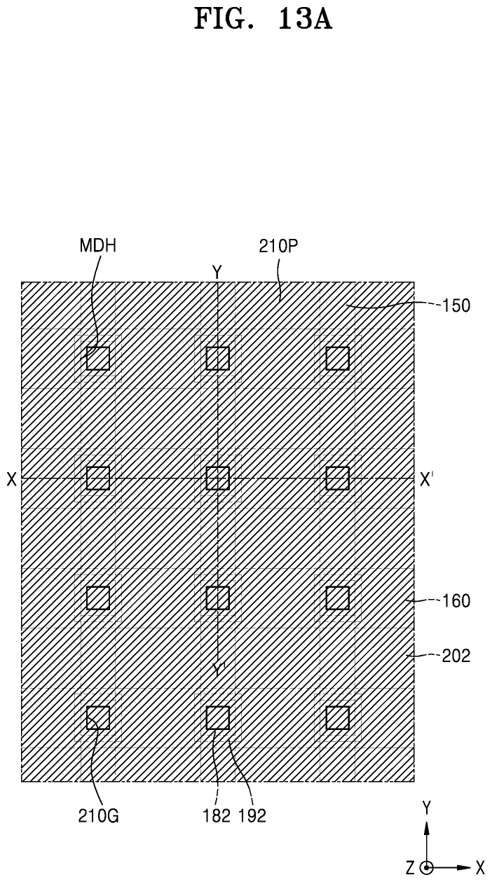

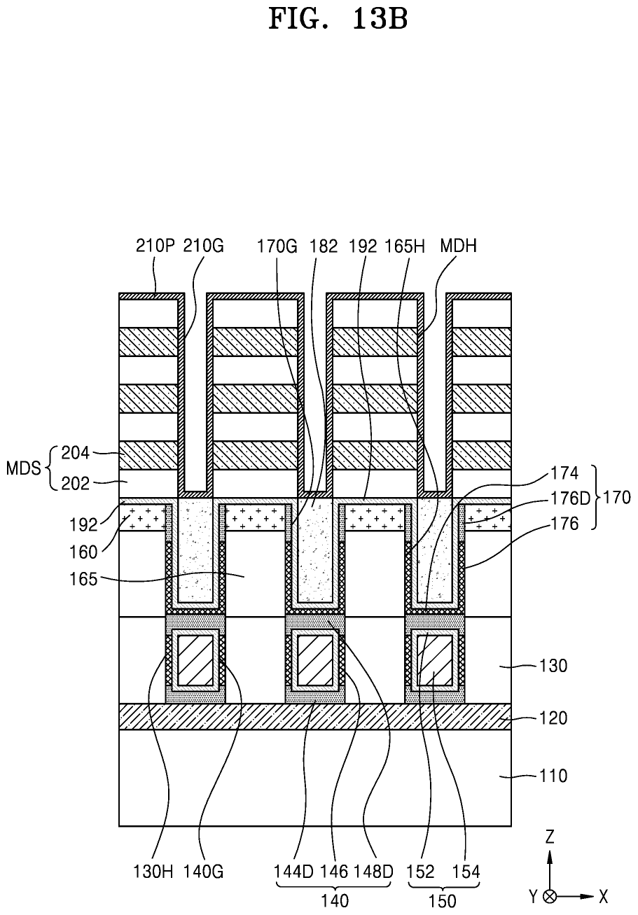

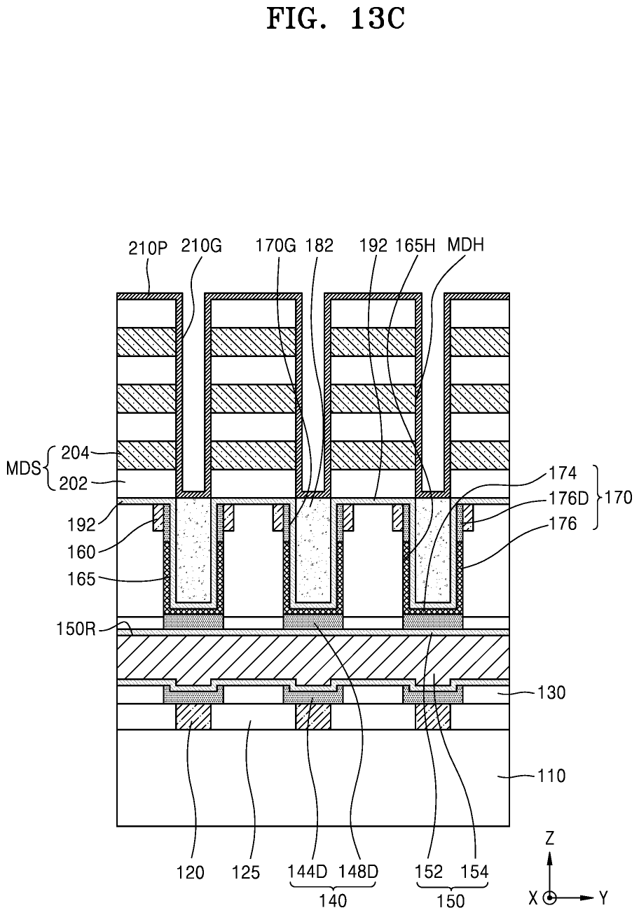

Referring to FIGS. 13A through 13C together, a ferroelectric layer 210P covering the inner surfaces and the bottom surfaces of the plurality of third holes MDH is formed. The ferroelectric layer 210P may be formed to cover the inner surfaces and the bottom surfaces of the plurality of third holes MDH, and the upper surface of the mold structure MDS, that is, an upper surface of the insulating layer 202 at the uppermost end among the plurality of insulating layers 202. For example, the ferroelectric layer 210P may be formed to conformally cover the side surfaces of the plurality of insulating layers 202 and the plurality of sacrificial layers 204, the upper surfaces of the plurality of second sacrificial layers 182, and the upper surface of the uppermost insulating layer 202 among the plurality of insulating layers 202. In some implementations, the ferroelectric layer 210P may be formed to have a relatively small thickness on the bottom surface of the plurality of third holes MDH. For example, when a material, such as a precursor, ion, or a gas for forming the ferroelectric layer 210P, is supplied to the bottom surfaces of the plurality of third holes MDH, a portion covering the bottom surfaces of the plurality of third holes MDH may be formed to have a smaller thickness than other portions covering the bottom surfaces thereof.

The ferroelectric layer 210P may be formed not to fill all of the plurality of third holes MDH. A plurality of fourth limited spaces 210G may be limited in the plurality of third holes MDH by the ferroelectric layer 210P.

For example, the ferroelectric layer 210P may include hafnium oxide, zirconium oxide, yttrium-doped zirconium oxide, yttrium-doped hafnium oxide, magnesium-doped zirconium oxide, magnesium-doped hafnium oxide, silicon-doped hafnium oxide, silicon-doped zirconium oxide, or barium-doped titanium oxide.

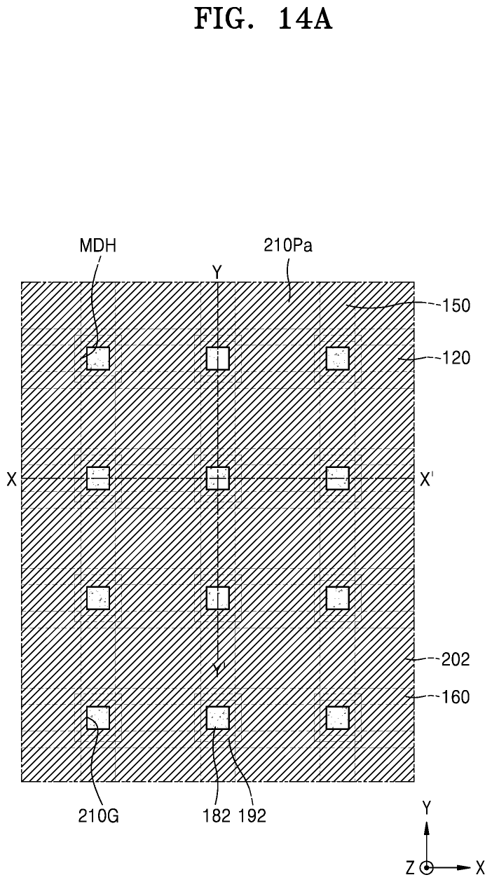

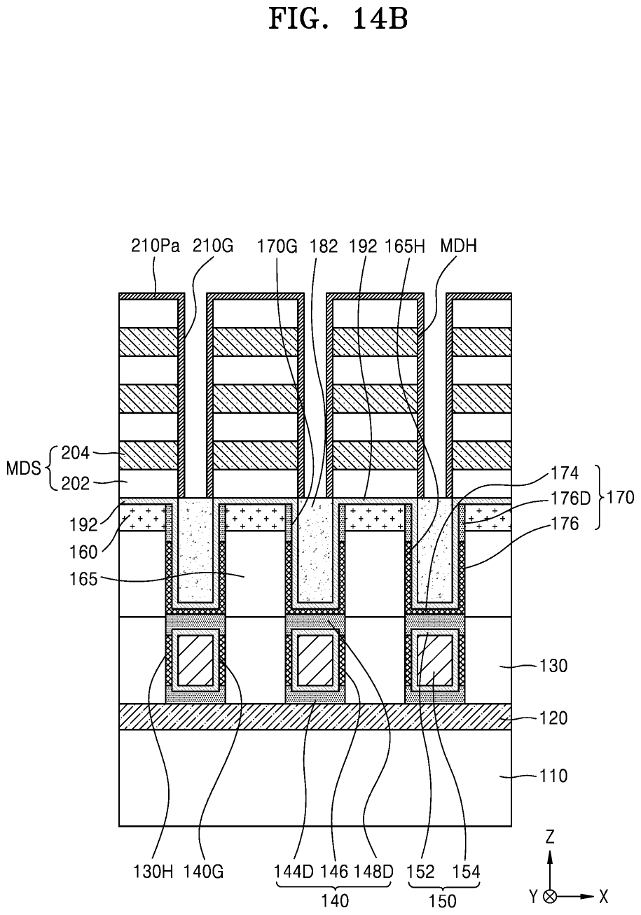

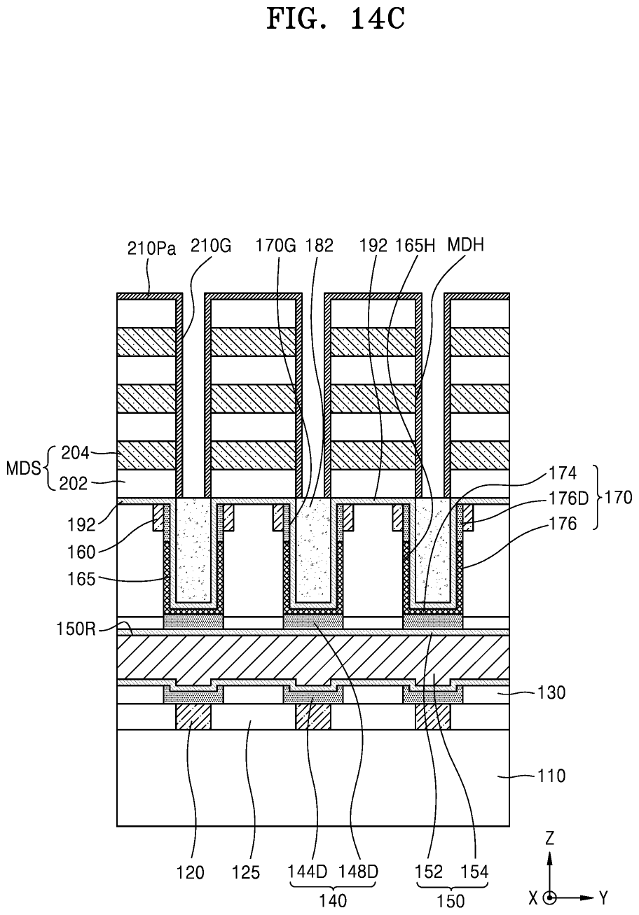

Referring to FIGS. 13A through 13C and 14A through 14C together, by removing portions of the ferroelectric layer 210P covering the plurality of second sacrificial layers 182, a ferroelectric pattern 210Pa is formed. The ferroelectric pattern 210Pa may be formed by removing portions of the ferroelectric layer 210P on the bottom surfaces of the plurality of third holes MDH. The plurality of second sacrificial layers 182 may be respectively exposed on the bottom surfaces of the plurality of third holes MDH and the bottom surfaces of the plurality of fourth limited spaces 210G.

In some implementations, in the process of removing portions of the ferroelectric layer 210P covering the plurality of second sacrificial layers 182, at least a portion covering an upper surface of the insulating layer 202 at the uppermost end among the plurality of insulating layers 202 of the ferroelectric layer 210P may be removed together. For example, when a thickness of portions of the ferroelectric layer 210P covering the plurality of second sacrificial layers 182 is less than a thickness of portions covering the upper surface of the insulating layer 202 at the uppermost end among the plurality of insulating layers 202, portions of the ferroelectric layer 210P covering the plurality of second sacrificial layers 182 may all be removed, but only certain portions covering the upper surface of the insulating layer 202 at the uppermost end among the plurality of insulating layers 202 may be removed and the other portions except the certain portions may remain on the upper surface of the insulating layer 202 at the uppermost end among the plurality of insulating layers 202.

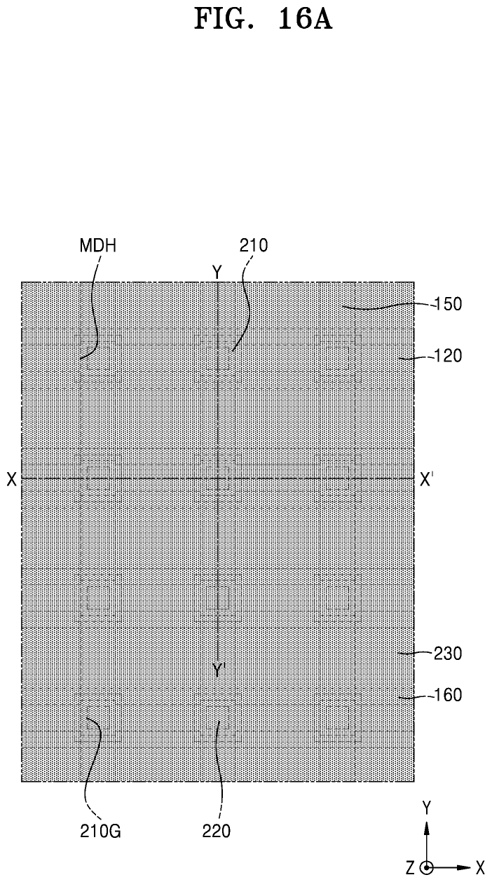

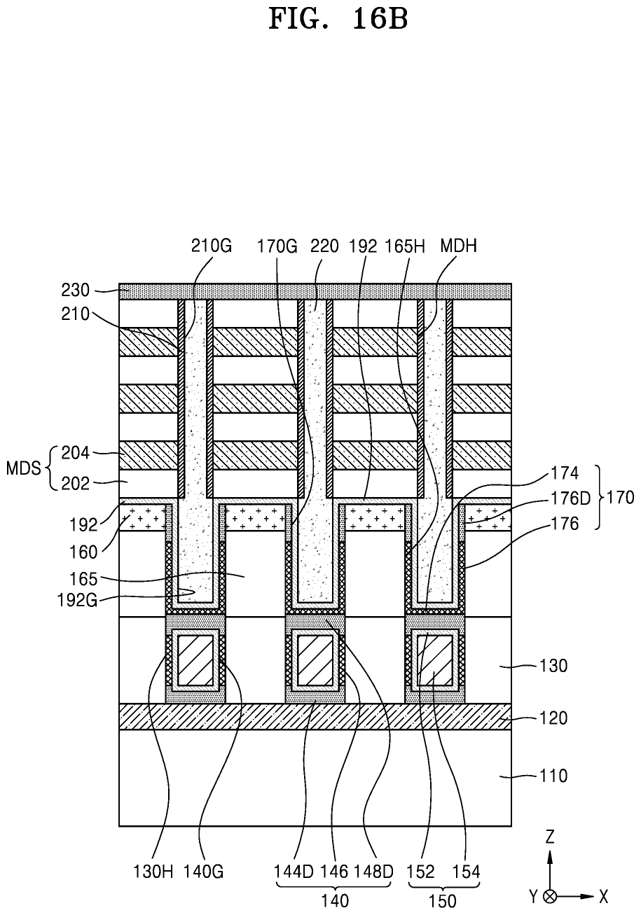

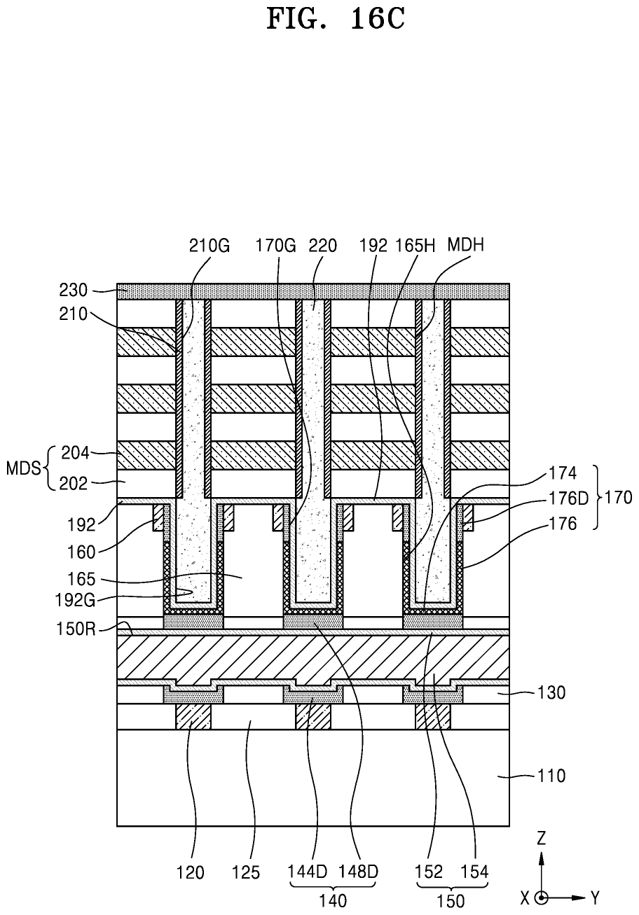

Alternatively, for example, when portions of the ferroelectric layer 210P covering the plurality of second sacrificial layers 182 and a portion covering the upper surface of the insulating layer 202 at the uppermost end among the plurality of insulating layers 202 are substantially the same, both the portions of the ferroelectric layer 210P covering the plurality of second sacrificial layers 182 and portions covering the upper surface of the insulating layer 202 at the uppermost end among the plurality of insulating layers 202 may be removed. When both the portions of the ferroelectric layer 210P covering the plurality of second sacrificial layers 182 and the portions covering the upper surface of the insulating layer 202 at the uppermost end among the plurality of insulating layers 202 are removed, a plurality of ferroelectric patterns 210 illustrated in FIGS. 16A through 16C may be formed instead of the ferroelectric pattern 210Pa.

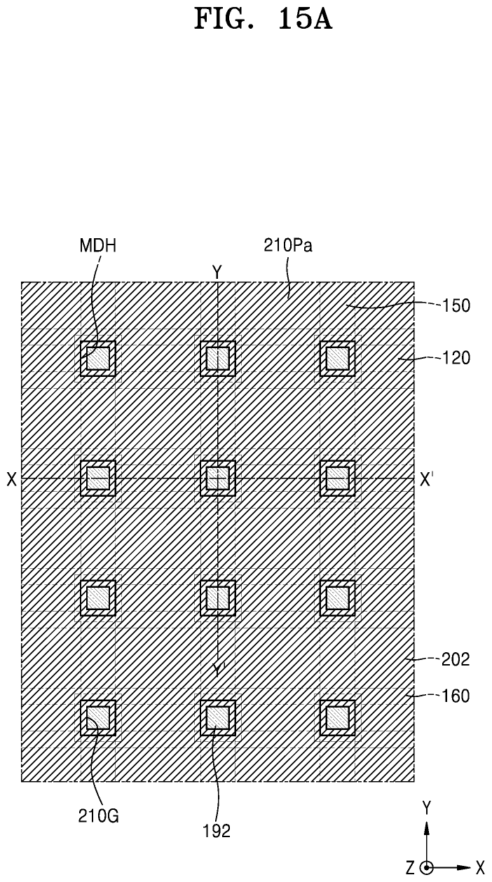

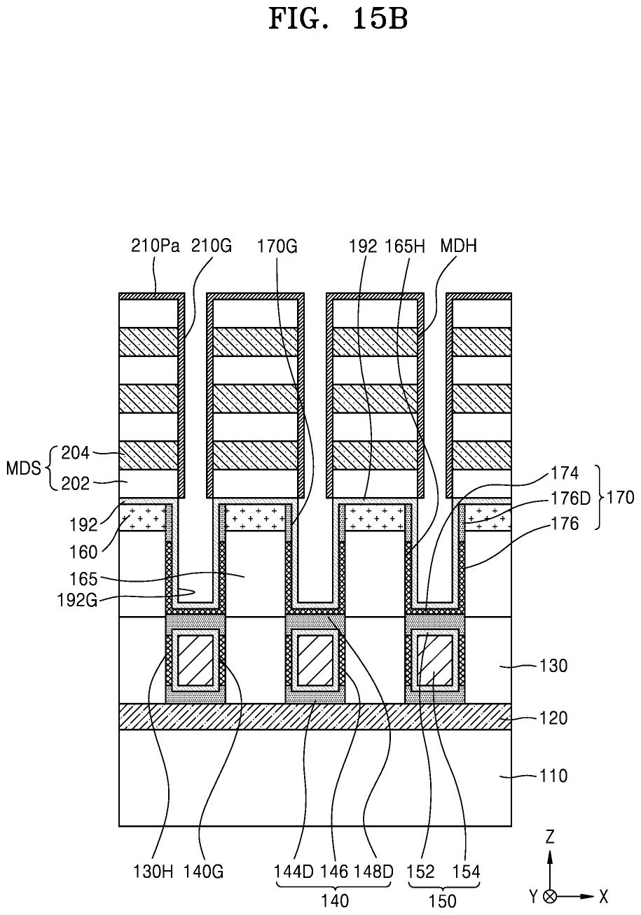

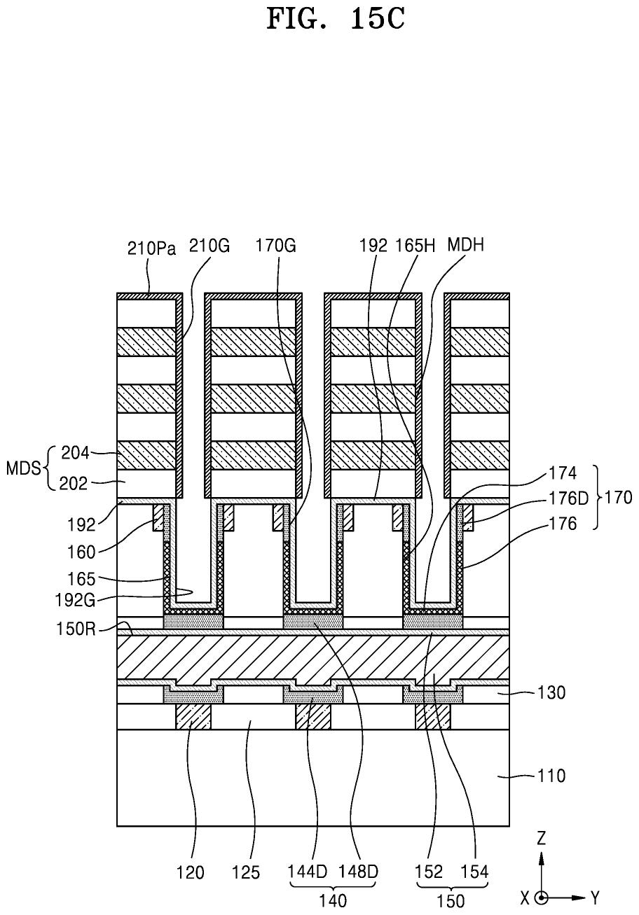

Referring to FIGS. 14A through 14C and 15A through 15C together, the plurality of second sacrificial layers 182 respectively filling the plurality of third limited spaces 192G are removed via the plurality of fourth limited spaces 210G. The ferroelectric pattern 210Pa is exposed in the plurality of fourth limited spaces 210G, and the second gate insulating layer 192 is exposed in the plurality of third limited spaces 192G.

Referring to FIGS. 15A through 15C and 16A through 16C together, a plurality of second gate electrodes 220 respectively filling the plurality of fourth limited spaces 210G and the plurality of third limited spaces 192G are formed. After a conductive material layer filling the plurality of fourth limited spaces 210G and the plurality of third limited spaces 192G and covering the mold structure MDS is formed, the plurality of second gate electrodes 220 are formed by removing a portion of the conductive material layer covering the mold structure MDS. In some implementations, the portion of the conductive material layer covering the mold structure MDS may be removed by performing a chemical mechanical polishing (CMP) process. Each of the plurality of second gate electrodes 220 may extend in the vertical direction (Z direction). The second gate electrode 220 may include the floating gate FG illustrated in FIG. 1.

When there is a portion of the ferroelectric pattern 210Pa covering the upper surface of the insulating layer 202 at the uppermost end among the plurality of insulating layers 202, in a process of removing the portion of the conductive material layer covering the mold structure MDS for forming the plurality of second gate electrodes 220, by removing the portion of the ferroelectric pattern 210Pa covering the upper surface of the insulating layer 202 at the uppermost end among the plurality of insulating layers 202, the plurality of ferroelectric patterns 210 may be formed. The plurality of ferroelectric patterns 210 may respectively cover the inner surfaces of the plurality of third holes MDH. For example, the plurality of ferroelectric patterns 210 may conformally cover the side surfaces of the plurality of insulating layers 202 and the plurality of sacrificial layers 204 exposed to the inner surfaces of the plurality of third holes MDH.

Lower side portions of the plurality of second gate electrodes 220 may be surrounded by the second gate insulating layer 192. For example, the lower side portions of the plurality of second gate electrodes 220 respectively filling the plurality of third limited spaces 192G may be surrounded by the second gate insulating layer 192. The second gate insulating layer 192 may cover the lower surfaces and side surfaces on a lower side portion of the plurality of second gate electrodes 220.

The upper portions of the plurality of second gate electrodes 220 may be respectively surrounded by the plurality of ferroelectric patterns 210. For example, the upper portions of the plurality of second gate electrodes 220 respectively filling the plurality of fourth limited spaces 210G may be surrounded by the plurality of ferroelectric patterns 210. The plurality of ferroelectric patterns 210 may cover side surfaces of an upper portion of the plurality of second gate electrodes 220.

After the plurality of second gate electrodes 220 are formed, a capping layer 230 covering the mold structure MDS, a plurality of ferroelectric patterns, and the plurality of second gate electrodes 220 may be formed.

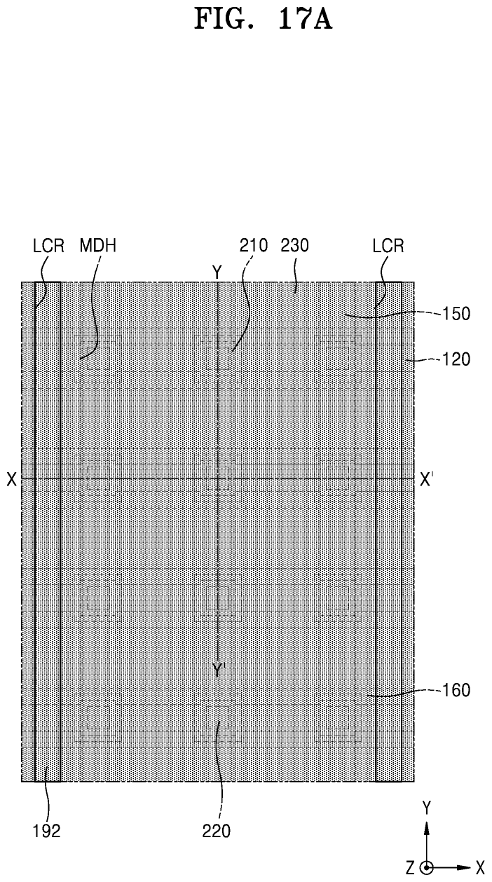

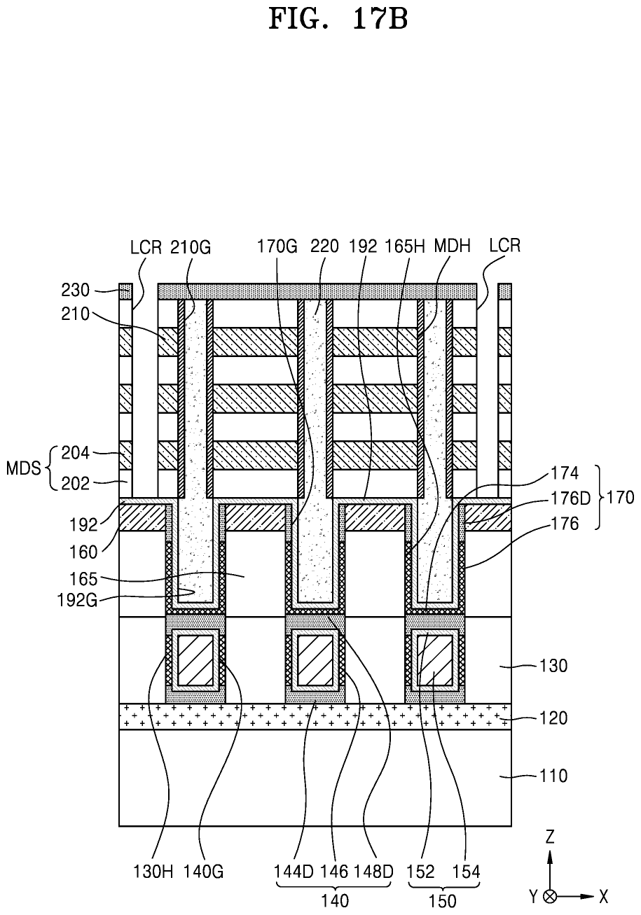

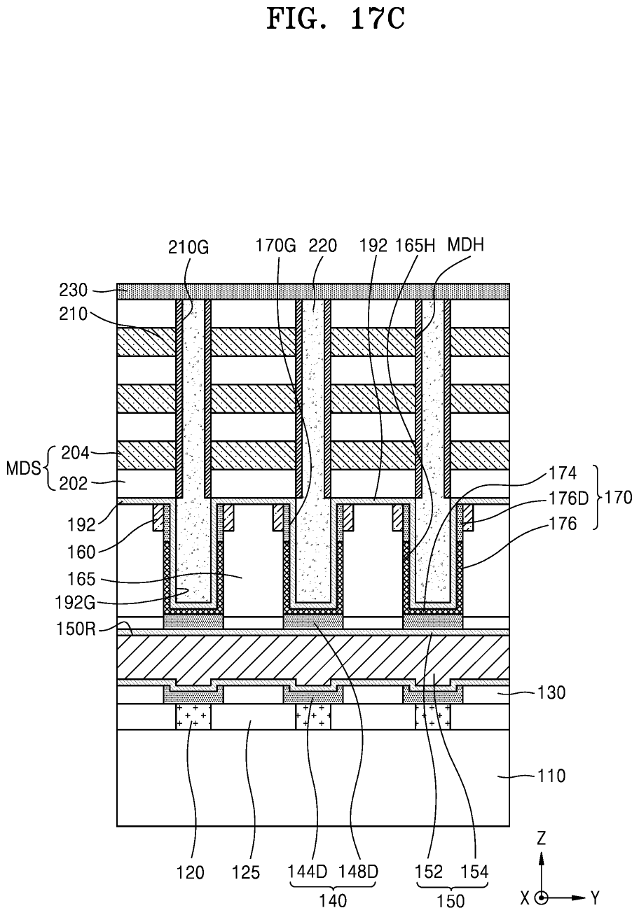

Referring to FIGS. 17A through 17C, a line cut region LCR penetrating the capping layer 230 and the mold structure MDS is formed. The line cut region LCR may be formed to extend in the second horizontal direction (Y direction). Although FIGS. 17A and 17B illustrate that three first gate structures 150 are arranged between a pair of line cut regions LCR apart from each other in the first horizontal direction (X direction), the implementations are not limited thereto. In some implementations, the first gate structures 150 corresponding to a divisor of the number of sacrificial layers 204 may be arranged between a pair of line cut regions LCR apart from each other in the first horizontal direction (X direction). For example, when the number of sacrificial layers 204 is three, the number of first gate structures 150 arranged between a pair of line cut regions LCR apart from each other in the first horizontal direction (X direction) may be three. Alternatively, for example, when the number of sacrificial layers 204 is 6, the number of first gate structures 150 arranged between a pair of line cut regions LCR apart from each other in the first horizontal direction (X direction) may be 6, 3, or 2.

Side surfaces of the plurality of insulating layers 202 and the plurality of sacrificial layers 204 re exposed on the inner surface of the line cut region LCR. The second gate insulating layer 192 re exposed on the bottom surface of the line cut region LCR, but is not limited thereto. For example, during the process of forming the line cut region LCR, a portion of the second gate insulating layer 192 may be removed, and the plurality of second conductive lines 160 may also be exposed on the bottom surface of the line cut region LCR.

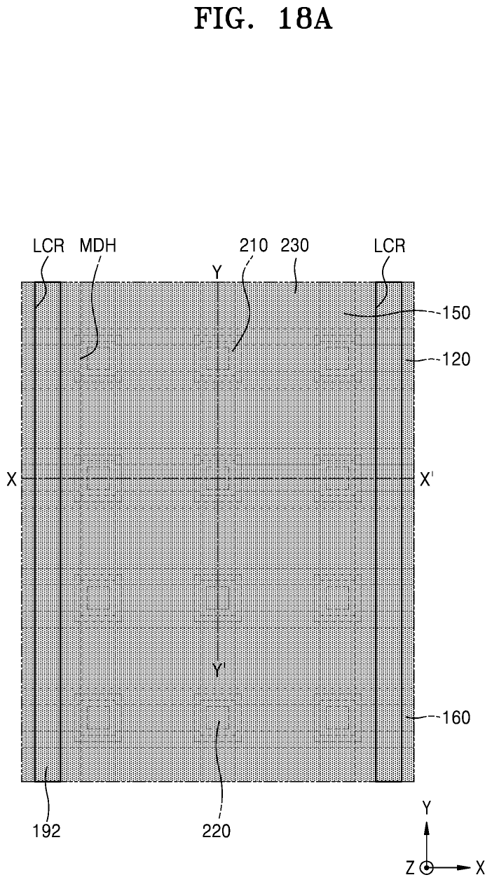

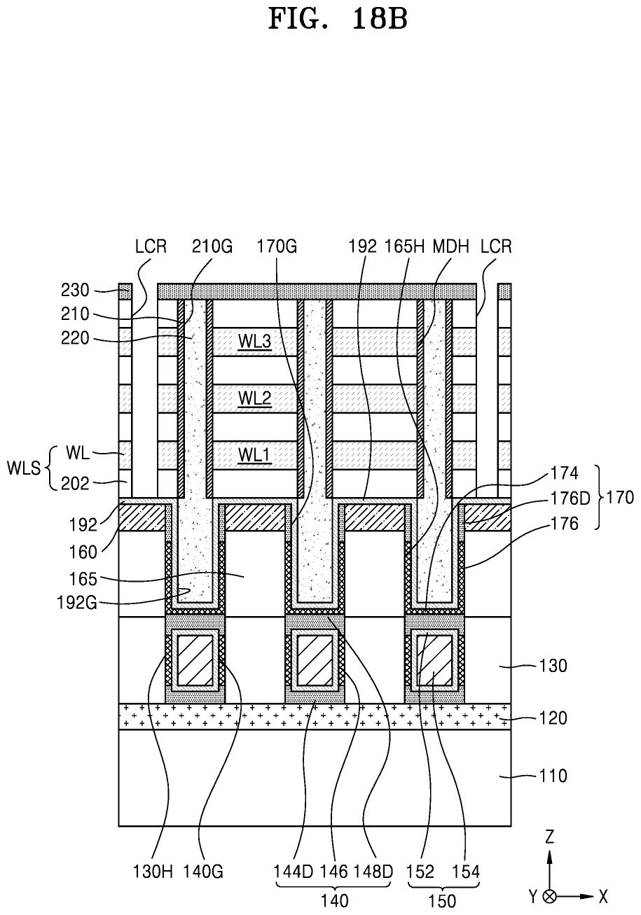

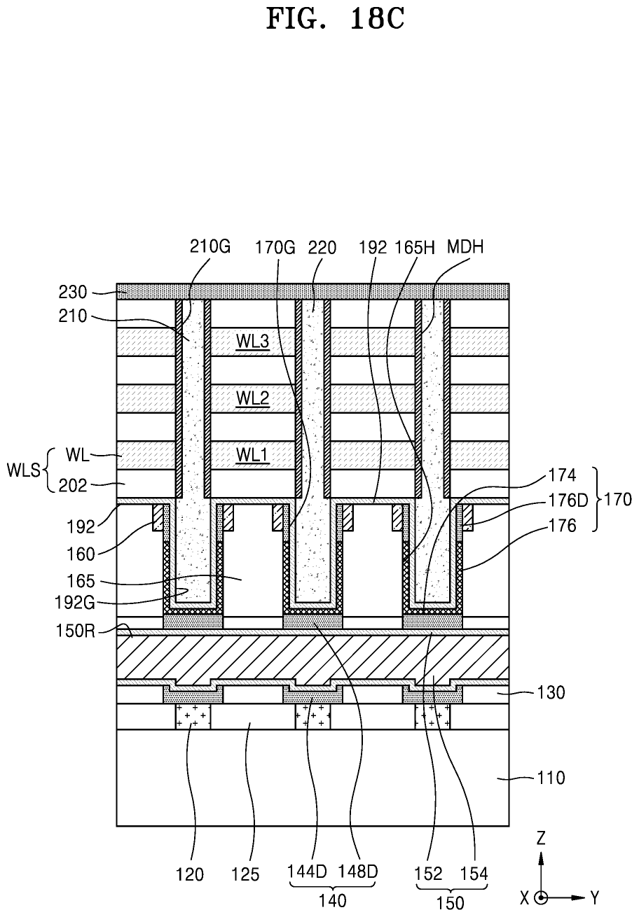

Referring to FIGS. 17A through 17C and 18A through 18C, after the plurality of sacrificial layers 204 are removed by using the line cut region LCR, a plurality of word lines WL filling the space are formed where the plurality of sacrificial layers 204 have been removed. After the conductive material layer fills the space where the plurality of sacrificial layers 204 have been removed and the line cut region LCR is formed, the plurality of word lines WL are formed by removing the portion of the conductive material layer filling the line cut region LCR. The word line WL may include the word line WL illustrated in FIG. 1.

Although the plurality of word lines WL may include the first word line WL1, the second word line WL2, and the third word line WL3, which are sequentially arranged from the substrate 110 in the vertical direction (Z direction), the implementation is only an example, and four or more word lines WL may be included. The plurality of insulating layers 202 and the plurality of word lines WL may constitute a word line stacked structure WLS. Each of the plurality of word lines WL may be arranged between two insulating layers 202 adjacent to each other among the plurality of insulating layers 202 in the vertical direction (Z direction). For example, the insulating layer 202 at the uppermost end among the plurality of insulating layers 202 may cover the upper surface of the word line WL at the uppermost end among the plurality of word lines WL, and the insulating layer 202 at the lowermost end among the plurality of insulating layers 202 may cover a lower surface of the word line WL at the lowermost end among the plurality of word lines WL.

In FIGS. 18A through 18C, the word line stacked structure WLS is illustrated to include four insulating layers 202 and three word lines WL, but the implementations are not limited thereto. For example, the word line stacked structure WLS may include five or more insulating layers 202 and four or more word lines WL.

Referring to FIGS. 19A through 19C, by forming a line cut insulating layer 250 filling the line cut region LCR, a semiconductor memory device 1 is formed.

The semiconductor memory device 1 includes the substrate 110, the plurality of first conductive lines 120 on the substrate 110, the plurality of first channel structures 140 on the plurality of first conductive lines 120, the plurality of first gate structure 150 including the plurality of first gate electrodes 154 and the plurality of first gate insulating layers 152 arranged in the plurality of first channel structures 140, a plurality of second channel structures 170 on the plurality of first channel structure 140, the plurality of second conductive lines 160 respectively connected to the plurality of second channel structures 170, the word line stacked structure WLS on the plurality of second channel structures 170 and the plurality of second conductive lines 160, the plurality of second gate electrodes 220 penetrating the word line stacked structure WLS and extending toward the substrate 110, a second gate insulating layer 192 arranged between the plurality of second gate electrodes 220 and the plurality of second channel structures 170, and the plurality of ferroelectric patterns 210 arranged between the plurality of second gate electrodes 220 and the word line stacked structure WLS. The lower side portion of the second gate electrode 220 filling the third limited space 192G, and a second gate insulating layer 192 arranged between the second gate electrode 220 and the second channel structure 170 may be referred to as a second gate structure together.

Each of the plurality of first channel structures 140 may include the first impurity region 144D, the first channel region 146, and the second impurity region 148D. Although the horizontal cross-section of each of the plurality of first channel structures 140 is illustrated as having a rectangular shape, the implementations are not limited thereto. For example, the horizontal cross-section of each of the plurality of first channel structures 140 may have a square, a rectangle, a circle, an oval, or a polygonal shape with four or more sides. The plurality of first channel structures 140 may surround the side surfaces, bottom surfaces, and top surfaces of the plurality of first gate structures 150. The first gate insulating layer 152 may be arranged between the first channel structure 140 and the first gate electrode 154.

The first impurity region 144D may include a portion of the first channel structure 140 that covers the lower surface of the first gate structure 150. The first impurity region 144D may be arranged between the first conductive line 120 and the first gate electrode 154. The first impurity region 144D may be in contact with the first conductive line 120. The first gate insulating layer 152 may be arranged between the first impurity region 144D and the first gate electrode 154. The first channel region 146 may include a portion of the first channel structure 140 covering the side surface of the first gate structure 150. The first gate insulating layer 152 may be arranged between the first channel region 146 and the first gate electrode 154. The second impurity region 148D may include a portion of the first channel structure 140 that covers the upper surface of the first gate structure 150. The first gate insulating layer 152 may be arranged between the second impurity region 148D and the first gate electrode 154.

The plurality of second channel structures 170 may be respectively arranged on a plurality of first channel structures 140. For example, each of the plurality of second channel structures 170 may be arranged on the second impurity region 148D of each of the plurality of first channel structures 140. Each of the plurality of second channel structures 170 may include the second channel region 176, the third impurity region 176D, and the second bottom surface portion 174. The second channel structure 170 may include the second bottom surface portion 174 in contact with the second impurity region 148D of the first channel structure 140. The second gate insulating layer 192 may be arranged between the second bottom surface portion 174 and the lower surface of the second gate electrode 220. In some implementations, at least a portion of the second bottom surface portion 174 may have impurities included in the second impurity region 148D being diffused thereinto, and may become a portion of the second impurity region 148D. In some implementations, at least a portion of the second bottom surface portion 174 may have impurities included in the second impurity region 148D not being diffused thereinto, and may become a portion of the second impurity region 148D.

The plurality of second channel structures 170 may surround a lower side portion of the plurality of second gate electrodes 220. The second gate insulating layer 192 may be arranged between the plurality of second channel structures 170 and the lower side portion of the plurality of second gate electrodes 220. The second channel region 176 may include the second gate insulating layer 192 and surround a portion of the side surface of the second gate electrode 220, or may include the second gate insulating layer 192 and surround a portion of the lower surface of the second gate electrode 220 and a portion of the side surface of the second gate electrode 220. The third impurity region 176D may be arranged on the second channel region 176, include the second gate insulating layer 192, and surround the other portion of the side surface of the second gate electrode 220. The third impurity region 176D may be in contact with the second conductive line 160.

The word line stacked structure WLS may include the plurality of insulating layers 202 and the plurality of word lines WL. The plurality of insulating layers 202 and the plurality of word lines WL may be alternately stacked on the plurality of second channel structures 170 and the plurality of second conductive lines 160. Each of the plurality of word lines WL may be arranged between two insulating layers 202 adjacent to each other among the plurality of insulating layers 202 in the vertical direction (Z direction). For example, the insulating layer 202 at the uppermost end among the plurality of insulating layers 202 may cover the upper surface of the word line WL at the uppermost end among the plurality of word lines WL, and the insulating layer 202 at the lowermost end among the plurality of insulating layers 202 may cover a lower surface of the word line WL at the lowermost end among the plurality of word lines WL.

The plurality of second gate electrodes 220 may penetrate the plurality of word line stacked structure WLS and the second conductive line 160, and extend toward the substrate 110. The lower side portion of the plurality of second gate electrodes 220 may include the second gate insulating layer 192 therebetween, and may be surrounded by the plurality of second channel structures 170. The upper side portion of the plurality of second gate electrodes 220 may include the plurality of ferroelectric patterns 210 therebetween, and may be surrounded by the word line stacked structure WLS.

The plurality of first conductive lines 120 may extend in parallel with each other in the first horizontal direction (X direction). The plurality of first conductive lines 120 may be arranged at equal intervals in the second horizontal direction (Y direction). The plurality of second conductive lines 160 may extend in parallel with each other in the first horizontal direction (X direction) on the plurality of first conductive lines 120. A plurality of second conductive lines 160 may be arranged at equal intervals in the second horizontal direction (Y direction). The first conductive line 120 may include the bit line BL illustrated in FIG. 1, and the second conductive line 160 may include the source line SL illustrated in FIG. 1.

The plurality of word lines WL may have a plate shape and extend in the first horizontal direction (X direction) and the second horizontal direction (Y direction), between the pair of line cut insulating layers 250 filling the pair of line cut regions LCR. The plurality of word lines WL may include the plurality of word lines WL illustrated in FIG. 1. The plurality of word lines WL may be arranged apart from each other in the vertical direction (Z direction). For example, the plurality of word lines WL may include three word lines WL including the first word line WL1, the second word line WL2, and the third word line WL3.

The plurality of first gate electrodes 154 may extend in parallel with each other in the second horizontal direction (Y direction). The plurality of first gate electrodes 154 may be arranged at an equal interval in the first horizontal direction (X direction). The first gate electrode 154 may include the control line CL illustrated in FIG. 1.

The plurality of second gate electrodes 220 may be arranged in columns and rows in the first horizontal direction (X direction) and the second direction (Y direction), and may extend in the vertical direction (Z direction). The second gate electrode 220 may include the floating gate FG illustrated in FIG. 1. The second gate electrode 220 may penetrate the plurality of word lines WL and the second conductive line 160, and extend into the second channel structure 170. The plurality of word lines WL and the second gate electrode 220 may be apart from each other with the ferroelectric pattern 210 therebetween. The second conductive line 160 and the second gate electrode 220 may be apart from each other with the second channel structure 170 and the second gate insulating layer 192 therebetween.

The first impurity region 144D, the first channel region 146, the second impurity region 148D, and the first gate structure 150 may constitute the first transistor CT illustrated in FIG. 1, that is, the control transistor. The first impurity region 144D, the first channel region 146, the second impurity region 148D, and the first gate electrodes 154 of the first gate structure 150 may function as a source, channel, drain, and gate of the first transistor CT, respectively. The second impurity region 148D, the second channel region 176, the third impurity region 176D, the second gate electrode 220, and the second gate insulating layer 192 may constitute the second transistor ST illustrated in FIG. 1, e.g., the storage transistor. The second impurity region 148D, the second channel region 176, the third impurity region 176D, and the second gate electrode 220 may function as a source, channel, drain, and gate of the second transistor ST, respectively. The second impurity region 148D may be shared to function as the drain of the first transistor CT and as the source of the second transistor ST together. Each of the first transistor CT and the second transistor ST may include a vertical channel transistor (VCT), in which a channel, e.g., each of the first channel region 146 and the second channel region 176, extends in the vertical direction (Z direction). The first transistor CT and the second transistor ST may be referred to as a first VCT and a second VCT, respectively.

A plurality of second gate electrodes 220, the plurality of ferroelectric patterns 210, and the plurality of word lines WL may constitute the plurality of ferroelectric capacitors CFE. The plurality of ferroelectric capacitors CFE may be arranged in columns and rows in the first horizontal direction (X direction) and the second horizontal direction (Y direction), and may be arranged apart from each other in the vertical direction (Z direction).

For example, the first word line WL1, the second gate electrode 220, and a portion of the ferroelectric pattern 210 arranged between the first word line WL1 and the second gate electrode 220 may constitute the first ferroelectric capacitor CFE1 illustrated in FIG. 1, the second word line WL2, the second gate electrode 220, and a portion of the ferroelectric pattern 210 arranged between the second word line WL2 and the second gate electrode 220 may constitute the second ferroelectric capacitor CFE2 illustrated in FIG. 1, and the third word line WL3, the second gate electrode 220, and a portion of the ferroelectric pattern 210 arranged between the third word line WL3 and the second gate electrode 220 may constitute the third ferroelectric capacitor CFE3 illustrated in FIG. 1. The first ferroelectric capacitor CFE1, the second ferroelectric capacitor CFE2, and the third ferroelectric capacitor CFE3 may be arranged apart from each other in the vertical direction (Z direction). Each of the first ferroelectric capacitor CFE1, the second ferroelectric capacitor CFE2, and the third ferroelectric capacitor CFE3 may be arranged in columns and rows in the first horizontal direction (X direction) and the second direction (Y direction).

The first transistor CT, the second transistor ST, and the plurality of ferroelectric capacitors CFE arranged in the vertical direction (Z direction) may constitute the memory cell UMC illustrated in FIG. 1. The plurality of memory cells UMC may be arranged in rows and columns in the first horizontal direction (X direction) and the second horizontal direction (Y direction) orthogonal to the first horizontal direction (X direction).

Because the semiconductor memory device 1 according to some implementations includes the plurality of memory cells UMC constituted by the plurality of first conductive lines 120 extending in the first horizontal direction (X direction), the plurality of first gate electrodes 154 extending in the second horizontal direction (Y direction), the plurality of second conductive lines 160 extending in the first horizontal direction (X direction), the second gate electrode 220 extending in the vertical direction (Z direction), and the plurality of word lines WL extending in each of the first horizontal direction (X direction) and the second horizontal direction (Y direction) and arranged apart from each other in the vertical direction (Z direction), the degree of integration of the semiconductor memory device 1 may be increased and the process difficulty thereof may be decreased.

In addition, by increasing the number of word lines WL apart from each other in the vertical direction (Z direction), the number of ferroelectric capacitors CFT may be increased, and thus the number of bits of information that may be stored in one memory cell UMC may be easily increased.

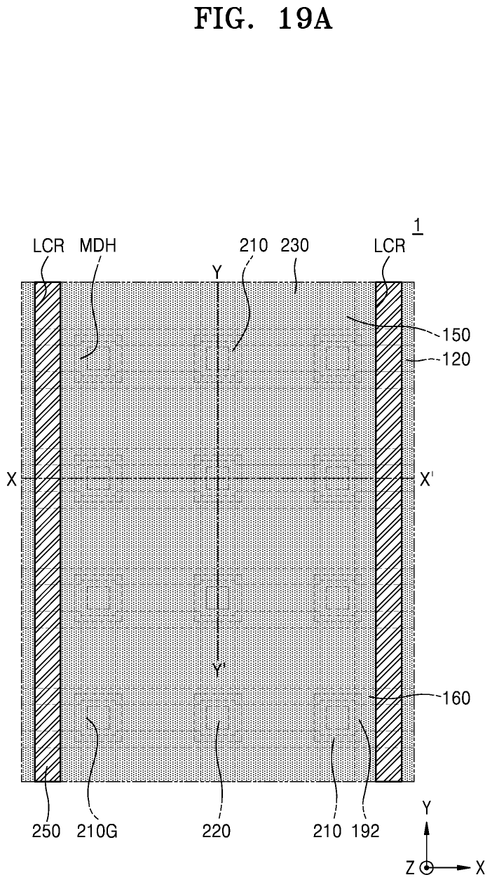

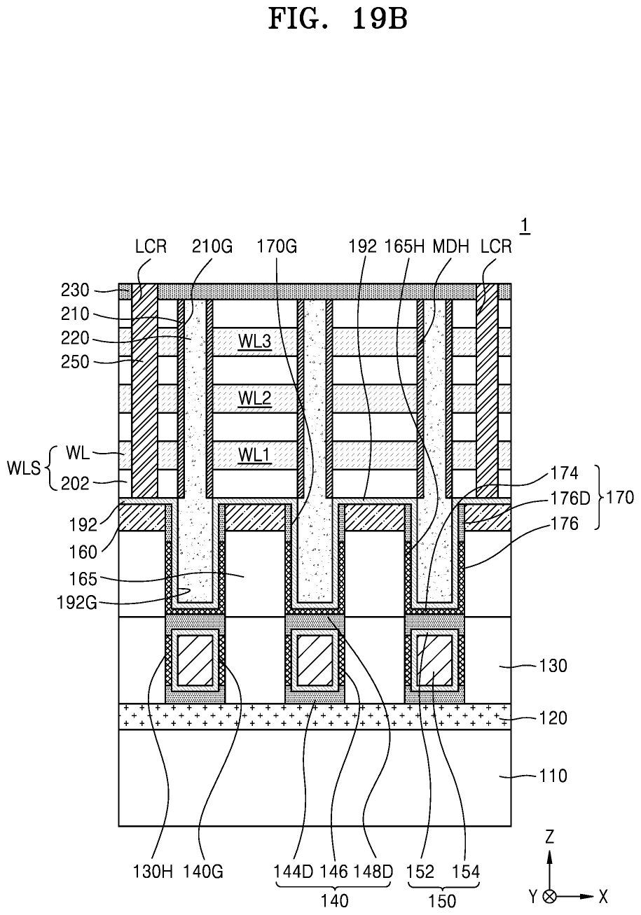

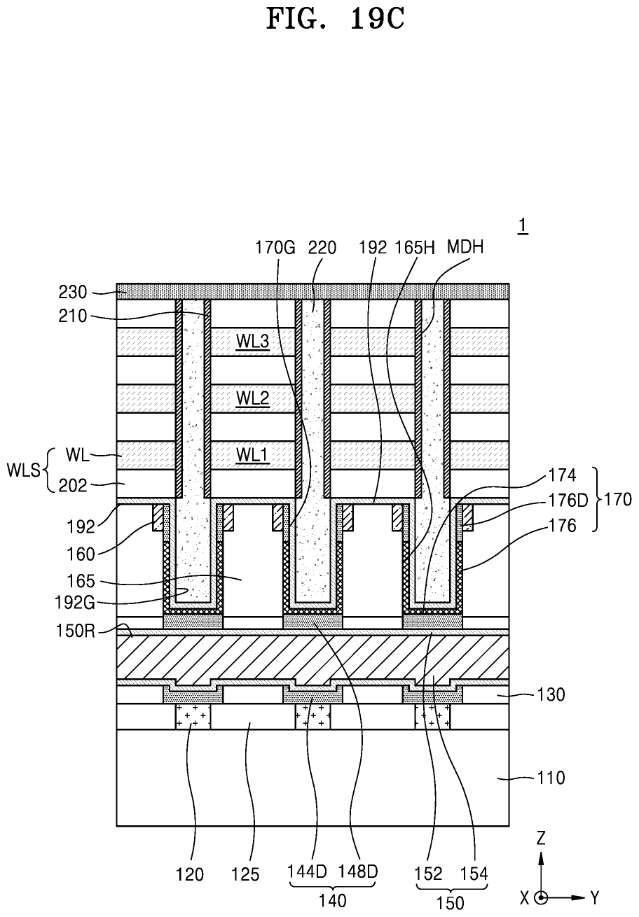

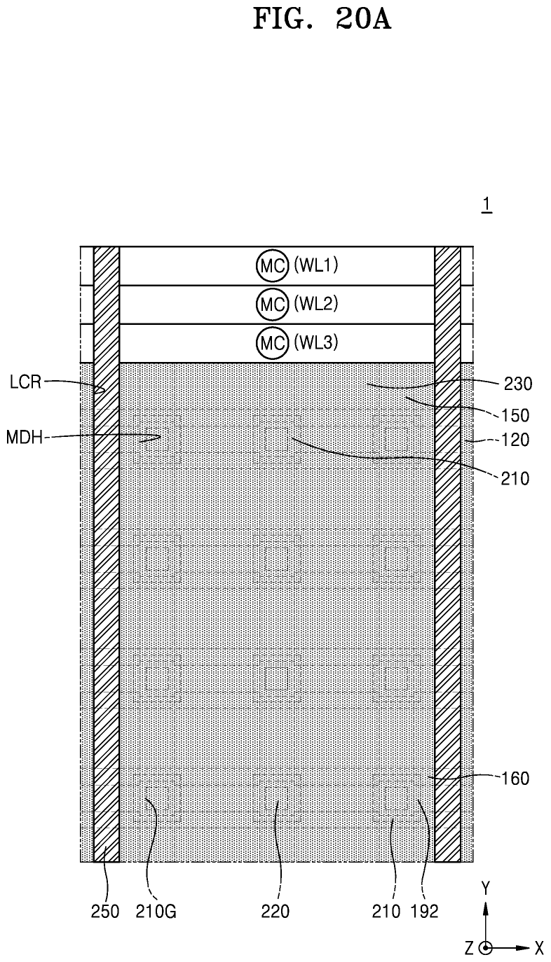

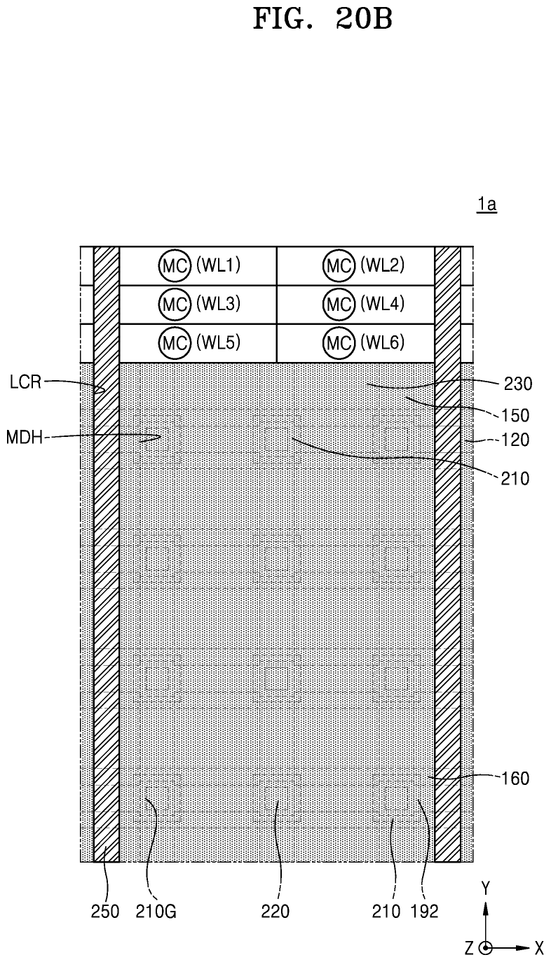

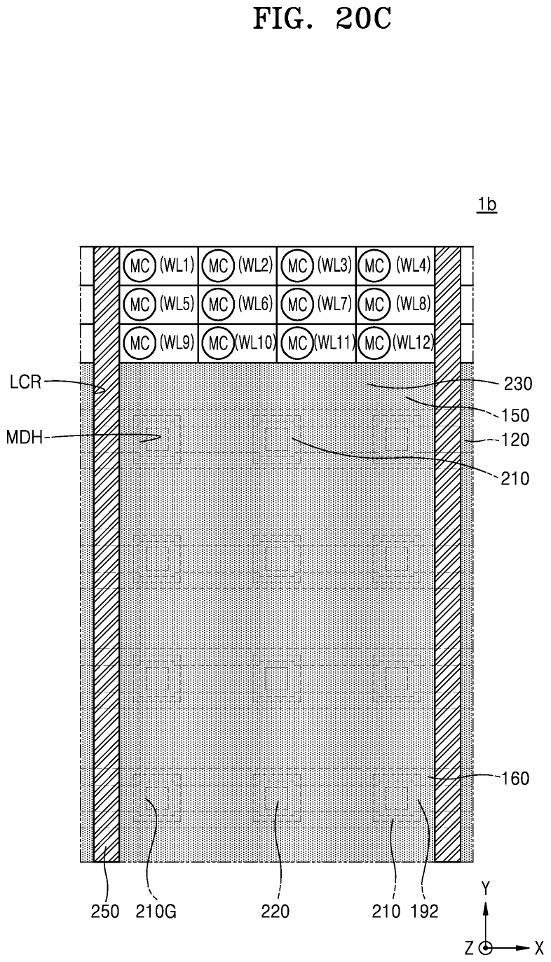

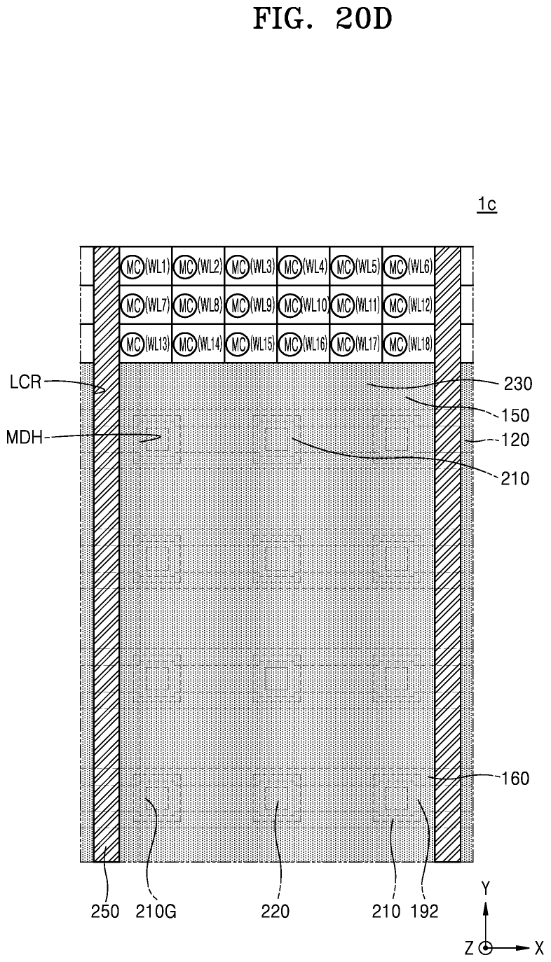

FIGS. 20A through 20D are plan views of the semiconductor memory device 1 according to some implementations.

Referring to FIG. 20A together with FIGS. 19B and 19C, the semiconductor memory device 1 includes the plurality of word lines WL arranged apart from each other in the vertical direction (Z direction). The plurality of word lines WL include three word lines WL including the first word line WL1, the second word line WL2, and the third word line WL3. The plurality of word lines WL may extend to different lengths in the second horizontal direction (Y direction), and form a stepped structure. For example, in the second horizontal direction (Y direction), an extension length of the first word line WL1 may be greater than an extension length of the second word line WL2, and the extension length of the second word line WL2 may be greater than an extension length of the third word line WL3. Due to the stepped structure, each of the plurality of word lines WL may include portions extending greater than other word lines WL adjacent to each other in the vertical direction (Z direction), and each of the portions may be referred to as a pad unit. A plurality of contact plugs MC may be respectively connected to the pad units of the plurality of word lines WL. In some implementations, each of the plurality of contact plugs MC may extend in the vertical direction (Z direction).

Referring to FIG. 20B, a semiconductor memory device 1a includes the first word line WL1, the second word line WL2, the third word line WL3, a fourth word line WL4, a fifth word line WL5, and a sixth word line WL6 apart from each other in the vertical direction (Z direction).

The first word line WL1, the third word line WL3, and the fifth word line WL5 may extend to different lengths in the second horizontal direction (Y direction) to form a stepped structure having a step shape, and the second word line WL2, the fourth word line WL4, and the sixth word line WL6 may extend to different lengths in the second horizontal direction (Y direction) to form a stepped structure having a step shape. In some implementations, in the second horizontal direction (Y direction), the first word line WL1 and the second word line WL2 may extend to the same length, the third word line WL3 and the fourth word line WL4 may extend to the same length, and the fifth word line WL5 and the sixth word line WL6 may extend to the same length. By using the stepped structure, the first word line WL1 may have a portion extending greater than the third word line WL3 in the vertical direction (Z direction), the third word line WL3 may have a portion extending greater than the fifth word line WL5 in the vertical direction (Z direction), the second word line WL2 may have a portion extending greater than the fourth word line WL4 in the vertical direction (Z direction), the fourth word line WL4 may have a portion extending greater than the sixth word line WL6 in the vertical direction (Z direction), and each of the portions may be referred to as the pad unit. The plurality of contact plugs MC may be connected to the pad units. In some implementations, each of the plurality of contact plugs MC may extend in the vertical direction (Z direction).

The pad unit of each of the first word line WL1, the third word line WL3, and the fifth word line WL5, and the pad unit of each of the second word line WL2, the fourth word line WL4, and the sixth word line WL6 may be arranged adjacent to each other in the first horizontal direction (X direction).

Referring to FIG. 20C, a semiconductor memory device 1b includes the first word line WL1, the second word line WL2, the third word line WL3, the fourth word line WL4, the fifth word line WL5, the sixth word line WL6, a seventh word line WL7, an eighth word line WL8, a ninth word line WL9, a tenth word line WL10, an eleventh word line WL11, and a twelfth word line WL12, which are sequentially apart from each other in the vertical direction (Z direction).

The first word line WL1, the fifth word line WL5, and the ninth word line WL9 may extend to different lengths from each other to form a stepped structure having a step shape, the second word line WL2, the sixth word line WL6, and the tenth word line WL10 may extend to different lengths from each other to form a stepped structure having a step shape, the third word line WL3, the seventh word line WL7, and the eleventh word line WL11 may extend to different lengths from each other to form a stepped structure having a step shape, and the fourth word line WL4, the eighth word line WL8, and the twelfth word line WL12 may extend to different lengths from each other to form a stepped structure having a step shape. In some implementations, in the second horizontal direction (Y direction), each of the first word line WL1, the second word line WL2, the third word line WL3, and the fourth word line WL4 may extend to the same length, each of the fifth word line WL5, the sixth word line WL6, the seventh word line WL7, and the eighth word line WL8 may extend to the same length, and each of the ninth word line WL9, the tenth word line WL10, the eleventh word line WL11, and the twelfth word line WL12 may extend to the same length. The plurality of contact plugs MC may be connected to the first word line WL1, the second word line WL2, the third word line WL3, the fourth word line WL4, the fifth word line WL5, the sixth word line WL6, the seventh word line WL7, the eighth word line WL8, the ninth word line WL9, the tenth word line WL10, the eleventh word line WL11, and the twelfth word line WL12. In some implementations, each of the plurality of contact plugs MC may extend in the vertical direction (Z direction).

Referring to FIG. 20D, a semiconductor memory device 1c includes the first word line WL1, the second word line WL2, the third word line WL3, the fourth word line WL4, the fifth word line WL5, the sixth word line WL6, the seventh word line WL7, the eighth word line WL8, the ninth word line WL9, the tenth word line WL10, the eleventh word line WL11, and the twelfth word line WL12, a thirteenth word line WL13, a fourteenth word line WL14, a fifteenth word line WL15, a sixteenth word line WL16, a seventeenth word line WL17, and an eighteenth word line WL18, which are sequentially apart from each other in the vertical direction (Z direction).

The first word line WL1, the seventh word line WL7, and the thirteenth word line WL13 may extend to different lengths from each other in the second horizontal direction (Y direction) to form a stepped structure having a step shape, the second word line WL2, the eighth word line WL8, and the fourteenth word line WL14 may extend to different lengths from each other in the second horizontal direction (Y direction) to form a stepped structure having a step shape, the third word line WL3, the ninth word line WL9, and the fifteenth word line WL15 may extend to different lengths from each other in the second horizontal direction (Y direction) to form a stepped structure having a step shape, the fourth word line W14, the tenth word line WL10, and the sixteenth word line WL16 may extend to different lengths from each other in the second horizontal direction (Y direction) to form a stepped structure having a step shape, the fifth word line WL5, and the eleventh word line WL11, and the seventeenth word line WL17 may extend to different lengths from each other in the second horizontal direction (Y direction) to form a stepped structure having a step shape, and the sixth word line WL6, and the twelfth word line WL12, and the eighteenth word line WL18 may extend to different lengths from each other in the second horizontal direction (Y direction) to form a stepped structure having a step shape. In some implementations, in the second horizontal direction (Y direction), each of the first word line WL1, the second word line WL2, the third word line WL3, the fourth word line WL4, the fifth word line WL5, and the sixth word line WL6 may extend to the same length, each of the seventh word line WL7, the eighth word line WL8, the ninth word line WL9, the tenth word line WL10, the eleventh word line WL11, and the twelfth word line WL12 may extend to the same length, and each of the thirteenth word line WL13, the fourteenth word line WL14, the fifteenth word line WL15, the sixteenth word line WL16, the seventeenth word line WL17, and the eighteenth word line WL18 may extend to the same length. The plurality of contact plugs MC may be respectively connected to the pad units of the first word line WL1, the second word line WL2, the third word line WL3, the fourth word line WL4, the fifth word line WL5, the sixth word line WL6, the seventh word line WL7, the eighth word line WL8, the ninth word line WL9, the tenth word line WL10, the eleventh word line WL11, the twelfth word line WL12, the thirteenth word line WL13, the fourteenth word line WL14, the fifteenth word line WL15, the sixteenth word line WL16, the seventeenth word line WL17, and the eighteenth word line WL18. In some implementations, each of the plurality of contact plugs MC may extend in the vertical direction (Z direction).

In FIGS. 20A through 20D, three pad units, to which the plurality of contact plugs MC are planarly connected, are arranged in the second horizontal direction (Y direction), and one, two, four, or six pad units are arranged in the first horizontal direction (X direction), but the implementations are not limited thereto. For example, one, two, or four or more pad units, to which the plurality of contact plugs MC are connected, may be planarly arranged in the second horizontal direction (Y direction), and three, five, or seven or more pad units may be arranged in the first horizontal direction (X direction).

In other words, a plurality of word lines included in a semiconductor memory device may extend in the second horizontal direction (Y direction) to form a stepped structure having a step shape, and the step shape may form a stepped structure having a step combination in the first horizontal direction (X direction) and the second horizontal direction (Y direction).

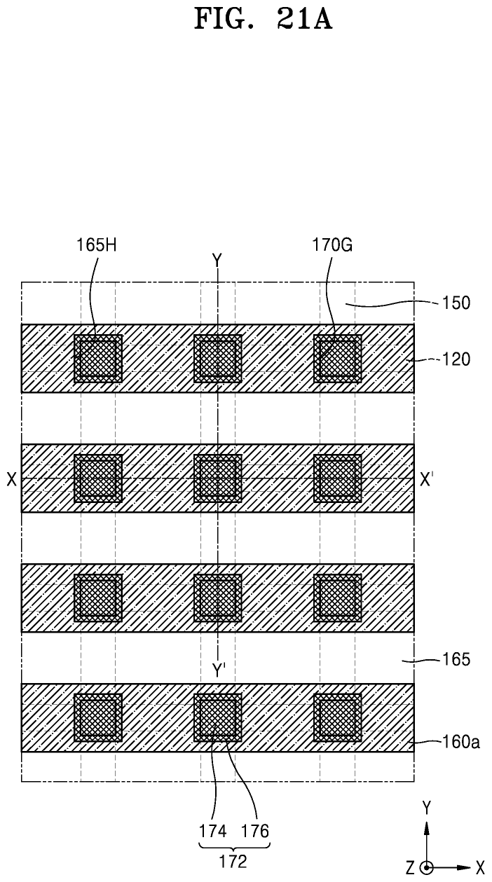

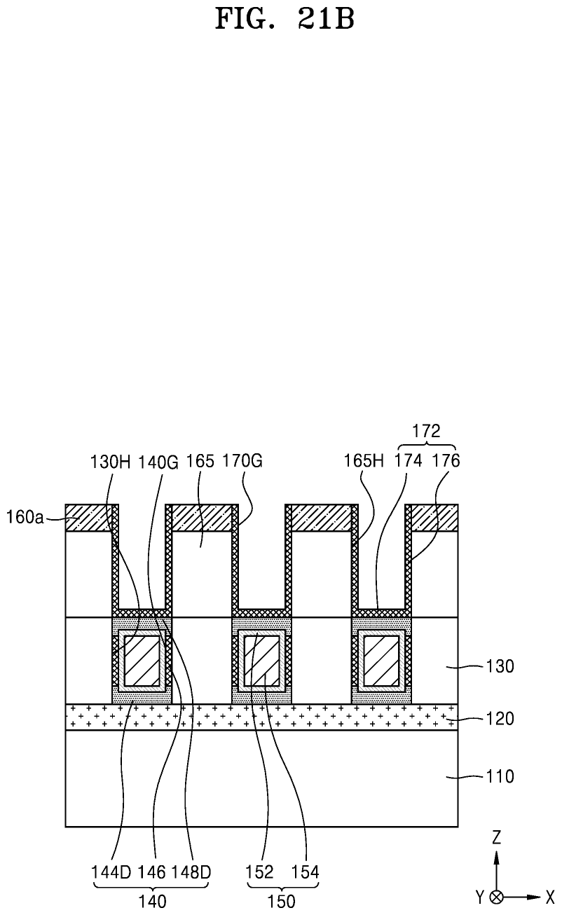

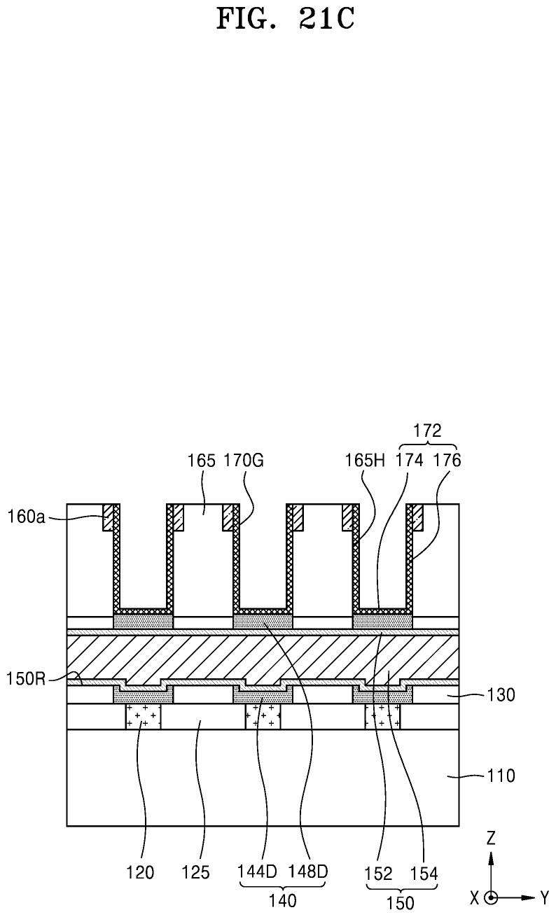

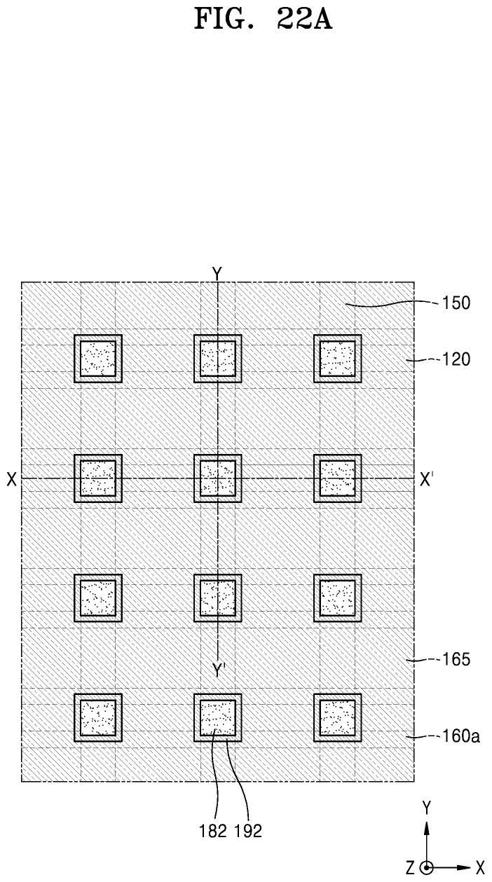

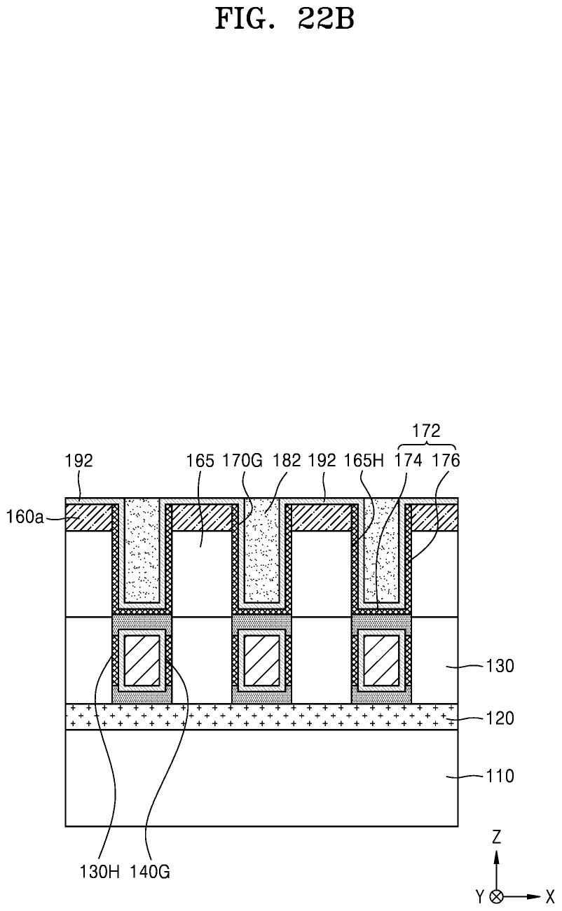

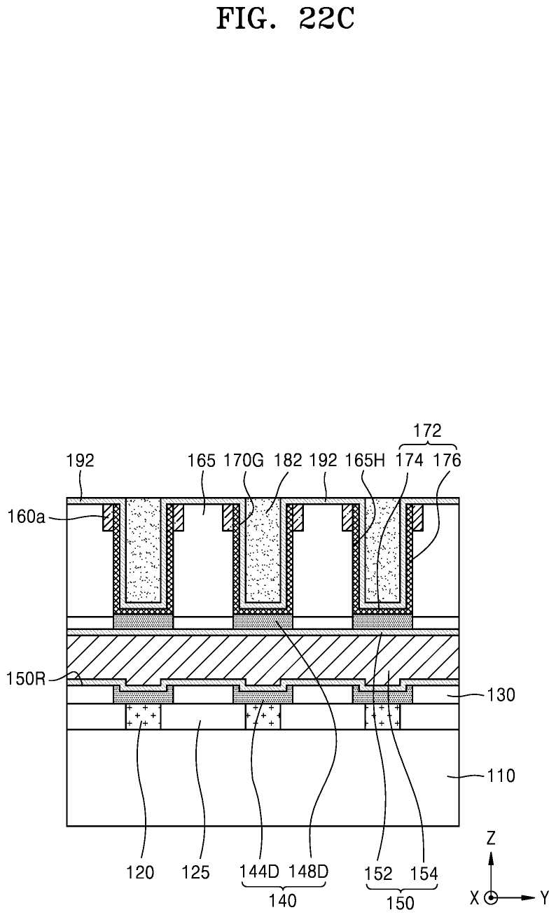

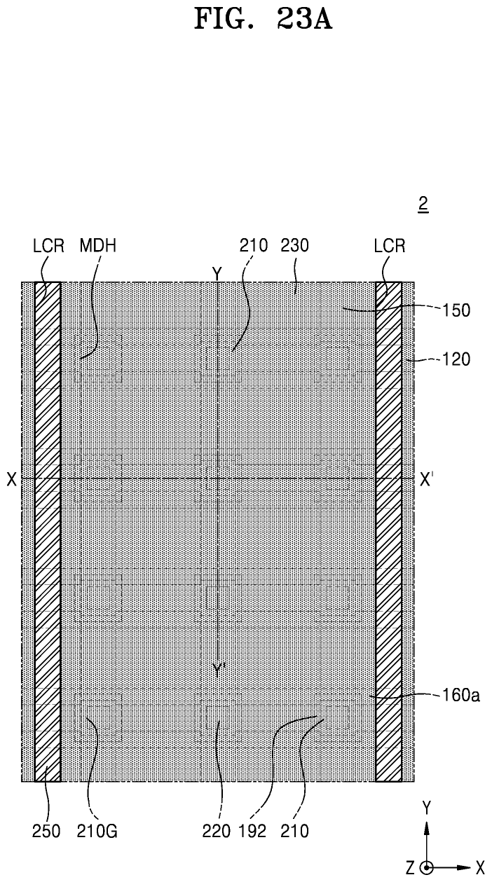

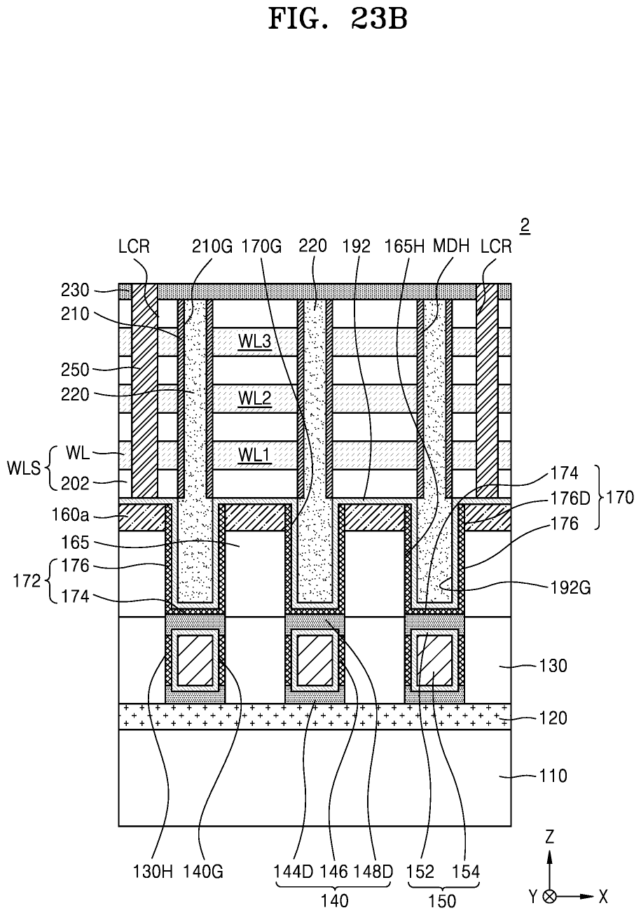

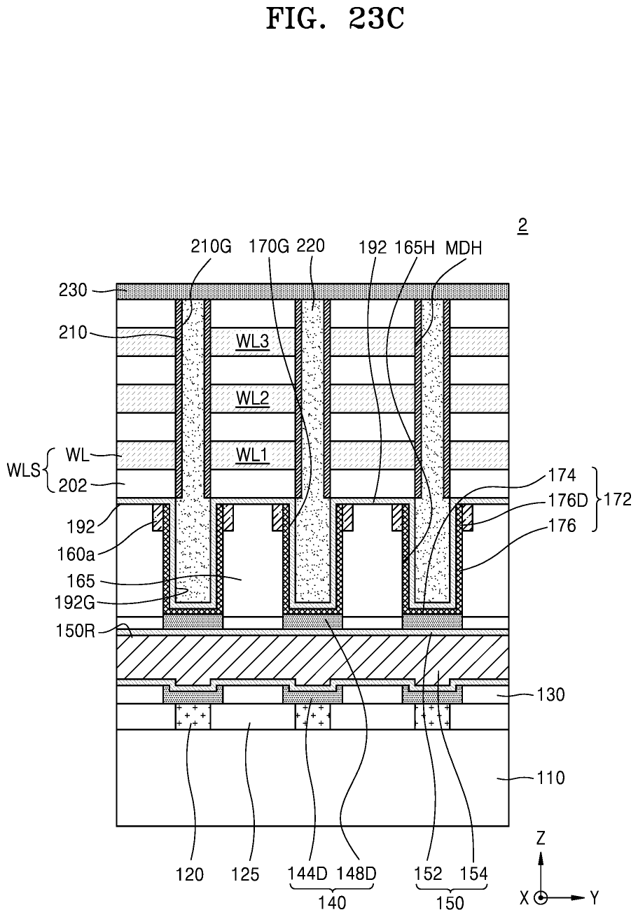

FIGS. 21A through 22C are diagrams illustrating a process sequence of a method of manufacturing a semiconductor memory device, according to some implementations, and FIGS. 23A through 23C are diagrams of a semiconductor memory device 2. FIGS. 21A, 22A, and 23A are plan views of semiconductor memory device according to some implementations, FIGS. 21B, 22B, and 23B are respective cross-sectional views taken along line X-X′ in FIGS. 21A, 22A, and 23A, and FIGS. 21C, 22C, and 23C are respective cross-sectional views taken along line Y-Y′ in FIGS. 21A, 22A, and 23A.

Referring to FIGS. 21A through 21C together, after a plurality of second conductive lines 160a are formed instead of the plurality of second conductive lines 160 illustrated in FIGS. 6A through 6C, and then, referring to FIGS. 7A through 8C, the plurality of second holes 165H and the plurality of second channel material layers 172 are formed.

The plurality of second conductive lines 160a may include doped polysilicon. For example, the plurality of second conductive lines 160a may include polysilicon doped with n-type impurities.

Referring to FIGS. 22A through 22C together, the second gate insulating layer 192 and the plurality of second sacrificial layers 182 are formed by, according to FIGS. 10A through 11C together, without forming the plurality of first sacrificial layers 180 and the plurality of third impurity regions 176D illustrated in FIGS. 9A through 9C.

Referring to FIGS. 23A through 23C together, a semiconductor memory device 2 is formed, after forming the word line stacked structure WLS, the plurality of ferroelectric patterns 210, the capping layer 230, the line cut region LCR, and the line cut insulating layer 250 according to FIGS. 12A through 19C. The portion of the second conductive line 160a adjacent to the second channel region 176 of each of the plurality of second channel material layers 172 may function as the third impurity region 176D described with reference to FIGS. 9A through 19C, and thus may be referred to as a third impurity region.

The first impurity region 144D, the first channel region 146, the second impurity region 148D, and the first gate structure 150 may constitute the first transistor CT illustrated in FIG. 1, that is, the control transistor. The second impurity region 148D, the second channel region 176, the third impurity region, which is a portion of the second conductive line 160a adjacent to the second channel region 176, the second gate electrode 220, and the second gate insulating layer 192 may constitute the second transistor ST illustrated in FIG. 1, that is, the storage transistor.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination

While the inventive concept has been particularly shown and described with reference to implementations thereof, it will be understood that various changes in form and details may be made therein without departing from the spirit and scope of the following claims.

What is claimed is:

1. A semiconductor memory device comprising:
a plurality of memory cells, wherein each memory cell of the plurality of memory cells includes: a first vertical channel transistor (VCT), and a second VCT arranged in a vertical direction and connected to each other in series,
wherein each memory cell of the plurality of memory cells further includes a plurality of ferroelectric capacitors connected in parallel to each other, wherein, for each memory cell, the plurality of ferroelectric capacitors are connected to the second VCT of the memory cell and arranged in the vertical direction,
wherein the plurality of memory cells are arranged in columns and rows in a first horizontal direction and a second horizontal direction that is different from the first horizontal direction.

2. The semiconductor memory device of claim 1, further comprising:
for each memory cell of the plurality of memory cells, a respective bit line connected to a source of the first VCT of the memory cell;
for each memory cell of the plurality of memory cells, a respective control line connected to a gate of the first VCT of the memory cell;
for each memory cell of the plurality of memory cells, a respective source line connected to a drain of the second VCT of the memory cell;
for each memory cell of the plurality of memory cells, a respective floating gate connected to a gate of the second VCT of the memory cell and connected to a first end of each ferroelectric capacitor of the plurality of ferroelectric capacitors of the memory cell; and
a plurality of word lines respectively connected to second ends of the plurality of ferroelectric capacitors.

3. The semiconductor memory device of claim 2, wherein a drain of the first VCT and a source of the second VCT share a same region.

4. The semiconductor memory device of claim 2, wherein the plurality of word lines are arranged apart from each other in the vertical direction.

5. The semiconductor memory device of claim 4, wherein each of the plurality of word lines has a plate shape and extends in the first horizontal direction and the second horizontal direction.

6. The semiconductor memory device of claim 2, wherein
the first horizontal direction and the second horizontal direction are orthogonal to each other,
the bit line and the source line extend in the first horizontal direction, and
the control line extends in the second horizontal direction.

7. The semiconductor memory device of claim 6, wherein the floating gate extends in the vertical direction.

8. The semiconductor memory device of claim 7, wherein the floating gate is apart from each of the plurality of word lines and the source line, and penetrates the plurality of word lines and the source line.

9. The semiconductor memory device of claim 8, further comprising a ferroelectric pattern arranged between the floating gate and the plurality of word lines, wherein the plurality of ferroelectric capacitors comprise the ferroelectric pattern.

10. A semiconductor memory device comprising:
a substrate;
a first conductive line on the substrate;
a first gate electrode on the first conductive line;
a first impurity region arranged between the first conductive line and the first gate electrode;
a first channel region surrounding side surfaces of the first gate electrode;
a second impurity region on the first channel region;
a second conductive line on the first gate electrode;
a plurality of word lines apart from each other in a vertical direction on the second conductive line;
a second gate electrode configured to penetrate the plurality of word lines and the second conductive line and extending on the first gate electrode;
one or more ferroelectric patterns arranged between the plurality of word lines and an upper side portion of the second gate electrode;
a second channel region surrounding side surfaces of a lower side portion of the second gate electrode on the second impurity region; and
a third impurity region connected to the second channel region,
wherein the first impurity region, the first channel region, the second impurity region, and the first gate electrode constitute a first vertical channel transistor (VCT), and
wherein the second impurity region, the second channel region, the third impurity region, and a lower side portion of the second gate electrode constitute a second VCT.

11. The semiconductor memory device of claim 10, wherein portions of the one or more ferroelectric patterns arranged between the upper side portion of the second gate electrode and the plurality of word lines constitute a plurality of ferroelectric capacitors arranged in the vertical direction, and
wherein the plurality of ferroelectric capacitors are connected to the second VCT in parallel via the second gate electrode.

12. The semiconductor memory device of claim 10, wherein the second impurity region is shared as a drain of the first VCT and a source of the second VCT.

13. The semiconductor memory device of claim 10, wherein the first conductive line and the second conductive line extend in a first horizontal direction, and
the first gate electrode extends in a second horizontal direction orthogonal to the first horizontal direction.

14. The semiconductor memory device of claim 10, wherein the second gate electrode is apart from each of the plurality of word lines and the second conductive line and extends in the vertical direction toward the substrate.

15. The semiconductor memory device of claim 10, wherein the third impurity region is arranged between the second gate electrode and the second conductive line on the second impurity region.

16. The semiconductor memory device of claim 10, wherein the third impurity region comprises a portion of the second conductive line adjacent to the second channel region.

17. The semiconductor memory device of claim 10, wherein the one or more ferroelectric patterns surround side surfaces of an upper side portion of the second gate electrode.

18. A semiconductor memory device comprising:
a substrate;
a first conductive line extending in a first horizontal direction on the substrate;
a first gate electrode extending in a second horizontal direction orthogonal to the first horizontal direction on the first conductive line;
a first channel structure including a first impurity region arranged between the first conductive line and the first gate electrode, a first channel region surrounding side surfaces of the first gate electrode, and a second impurity region connected to the first channel region and covering the first gate electrode;
a second conductive line extending in the first horizontal direction on the first gate electrode;
a plurality of word lines apart from each other in a vertical direction on the second conductive line;
a second gate electrode apart from the plurality of word lines and the second conductive line on the first gate electrode, wherein the second gate electrode is configured to penetrate the plurality of word lines and the second conductive line and extending in the vertical direction toward the substrate;
a ferroelectric pattern arranged between the plurality of word lines and the second gate electrode, and surrounding side surfaces of an upper side portion of the second gate electrode; and
a second channel structure surrounding side surfaces of a lower side portion of the second gate electrode, the second channel structure including a third impurity region connected to the second channel region and arranged between the second conductive line and the second gate electrode,
wherein the first impurity region, the first channel region, the second impurity region, and the first gate electrode constitute a first vertical channel transistor (VCT),
wherein the second impurity region, the second channel region, the third impurity region, and the lower side portion of the second gate electrode constitute a second VCT connected to the first VCT in series, and
wherein portions of the ferroelectric pattern arranged between the upper side portion of the second gate electrode and the plurality of word lines constitute a plurality of ferroelectric capacitors arranged in the vertical direction and connected to the second VCT in parallel.

19. The semiconductor memory device of claim 18, wherein a horizontal direction width of the second conductive line is greater than a horizontal direction width of the first conductive line, in the second horizontal direction.

20. The semiconductor memory device of claim 18, wherein the first impurity region, the first channel region, the second impurity region, and the first gate electrode comprise a source of the first VCT, a channel of the first VCT, a drain of the first VCT, and a gate of the first VCT, respectively,
wherein the second impurity region, the second channel region, the third impurity region, and the lower side portion of the second gate electrode comprise a source of the second VCT, a channel of the second VCT, a drain of the second VCT, and a gate of the second VCT, respectively, and
wherein the second impurity region is shared as the drain of the first VCT and the source of the second VCT.
